(19) United States
(12) Patent Application Publication
(10) Pub. No.: US 2006/0065186 A1
(43) Pub. Date: Mar. 30, 2006

(54) Process for producing crystalline thin film

(75) Inventor: Hideya Kumoni, TOKYO (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/535,196

(22) PCT Filed: Dec. 9, 2003
(86) PCT No.: PCT/JP03/15717

§ 371 Date: May 18, 2005

(30) Foreign Application Priority Data
Dec. 10, 2002 (JP) 2002-358162
Jun. 11, 2003 (JP) 2003-165856

(51) Int. Cl. C30B 23/00; C30B 25/00; C30B 28/12; C30B 28/14

(52) U.S. Cl. 117/92; 117/90; 117/94

(57) ABSTRACT

The invention provides a process for producing a crystalline thin film, characterized by including the steps of: (A) preparing a thin film having a specific region arranged at a predetermined position, the specific region continuing to a surrounding non-specific region and being different in melting or resolidification property from the surrounding non-specific region; (B) locally melting and resolidifying a partial area including the specific region in the thin film; and (C) locally melting and resolidifying another partial area including a non-specific region sharing a common boundary with an area crystallized by resolidification in a preceding step. The spatial position of the specific region can be accurately determined. The obtained crystalline thin film has crystal grains formed at predetermined positions, and therefore the fluctuation of formed elements are reduced.

### TECHNICAL FIELD

The present invention relates to a process for producing a crystalline thin film which is useful for large-scale integrated circuits requiring high spatial uniformity such as in flat panel displays, image sensors, magnetic recording devices, and information/signal processors; an element employing the crystalline thin film; and a circuit employing the element.

### BACKGROUND ART

Flat panel displays such as liquid crystal displays have been improved in fineness, display speed, and gradation of image display by monolithic implementation of an image driving circuit to the panel. The simple matrix-driven panels have been replaced with active matrix-driven panels having a switching transistor for each of pixels. At present, ultra-fine full-color liquid crystal displays are provided to be suitable for moving pictures by implementing a shift resistor circuit on the periphery of the same panel for driving the active matrix.

The monolithic implementation including the peripheral driving circuit can be produced at a practical production cost mainly owing to development of the technique for forming a polycrystalline silicon thin film having excellent electrical performance on an inexpensive glass substrate. This is a technique in which amorphous silicon thin film deposited on a glass substrate is molten and resolidified to form a polycrystalline thin film by a short-time pulse projection of light of ultraviolet region such as an excimer laser while keeping the glass substrate at a low temperature. The crystal grain obtained by melting-resolidification has a low defect density in the grain in comparison with crystal grains obtained from the same amorphous silicon thin film by solid-phase crystallization into a polycrystalline thin film. Thereby, the thin film transistor constituted by using this thin film as the active region exhibits a high carrier mobility. Therefore, even with the polycrystalline thin film having an average grain size up to a submicron, an active matrix-driven monolithic circuit can be produced which exhibits sufficient performance in a liquid crystal display having a fineness of 100 ppi or lower in diagonal display size of several inches.

However, it has become clear that the current thin film transistor employing the polycrystalline silicon thin film produced by melting-resolidification is still insufficient in performance for a liquid crystal display of the next generation having a larger screen or a higher fineness. Furthermore, the aforementioned polycrystalline silicon thin film is in sufficient in the performance as the driving circuit element in promising future application fields of plasma displays and electroluminescence displays driven at a higher voltage or larger electric current than the liquid crystal display, or in the application fields of a medical large-screen X-ray image sensor. The polycrystalline silicon thin film, which has average grain size up to submicron, cannot give a high-performance element even with the low defect density in the grain, because of many grain boundaries which hinder charge transfer in the active region of the element having a size of about a micron.

One of methods for reducing the grain boundary density in the polycrystalline thin film and the spatial dispersion thereof at the same time is the zone melting recrystallization method (ZMR method).

In the ZMR method, a partial area of a starting thin film is locally heated and molten, and the molten area is continuously scanned within the surface of the thin film, whereby continuous solidification and crystallization are performed with a crystal grain already solidified at the end of a beltlike region opposite to the scanning direction as a seed crystal. The crystal grain formed through melting-resolidification has a beltlike shape being long in the scanning direction and growing in the lateral direction, and an in-plane two-way component of grain boundary density becomes maximum in the scanning direction. In other words, the position of the grain boundary is one-dimensionally controlled. As a result, the grain boundary density decreases.

The ZMR method was originally invented as one of techniques for fabricating an SOI substrate by melting-recrystallization of a silicon thin film having a thickness of about a micron on a silicon substrate with an oxide film. Recently, a result of applying just the same idea to formation of a low-temperature polycrystalline silicon thin film for the purpose of application to a TFT on a glass substrate has been reported.

Hara et al. applied a linear continuous oscillation laser beam to an amorphous silicon thin film having a thickness of 50 to 150 nm while scanning at a rate of several 10 centimeters per second (A. Hara, F. Takeuchi, M. Takei, K. Suga, K. Yoshino, M. Chiba, Y. Sano, and N. Sasaki, Jpn. J. Appl. Phys., Part 2, Vol. 41, pp. L311-L313 (2002); and A. Hara, F. Takeuchi, M. Takei, K. Suga, K. Yoshino, M. Chiba, Y. Sano, and N. Sasaki, AM-LCD '02 Digest of Technical Papers, pp. 227-230 (2002)).

Tai et al. applied a linear continuous oscillation laser beam to an amorphous silicon thin film having a thickness of 50 nm while scanning at a rate of several centimeters per second (M. Tai, M. Hatano, S. Yamaguchi, S. K. Park, T. Noda, M. Hongo, T. Shiba, and M. Ohkura, AM-LCD '02 Digest of Technical Papers, pp. 231-234 (2002)).

In any case, beltlike crystal grains extending long in the scanning direction of the laser beam and having a maximum width of several μms grew, and the highest performance of the TFT fabricated here was equivalent to that of a transistor on a monocrystal silicon. However, the TFT characteristics considerably varied in comparison with the transistor on the monocrystal silicon, and when the TFT was used to form a circuit, the performance of the circuit was far inferior to that on the monocrystal silicon.

Imperfectness in control of the position of the grain boundary is a reason for significant variations among two or more TFTs in the example of the conventional technique described above. That is, the position of the grain boundary is one-dimensionally controlled due to lateral growth of the beltlike crystal grain along the scanning direction of the laser beam, but adjacent crystal grains having different sizes of belt widths are randomly arranged. Furthermore, the width is not necessarily constant in the scanning direction, and there are not a few locations where the grain boundary extends aslant. Consequently, the grain boundary density of a channel region of the TFT has fluctuation as ever, resulting in limitation on the performance of a circuit having the TFT as a component.

As a method, other than the ZMR method, for decreasing the grain boundary density in the polycrystalline thin film and the spatial dispersion thereof at the same time, Im et al. proposed sequential lateral solidification (hereinafter abbreviated as SLS method) (R. S. Sposili and J. S. Im, Appl. Phys. Lett. Vol. 69, 2864 (1996); Japanese Patent No. 03204986).

It can be said that the SLS method is a method in which sequential shift of the melting-resolidified area by short-time pulses of heating and cooling is performed and repeated instead of the scanning of the molten area in continuous lateral growth of the crystal grain by scanning type melting-resolidification as in the former zone melting recrystallization method.

In the example reported in the document described above, a laser beam having a width of 5 μm was sequentially applied with the laser beam being shifted by 0.75 μm in the direction of width for one shot in excimer laser crystallization of an amorphous silicon thin film.

In the first shot, the 5 μm-wide region irradiated with the laser beam is in a random polycrystal state but in the second shot, a polycrystal group melting-resolidified in the first shot contacts the end of the completely molten 5 μm-wide region on the first shot side, and therefore lateral growth occurs with crystal grains constituting the polycrystal group contacting the solid-liquid interface as seed crystals. In the third shot and subsequent shots, lateral growth is further continued with the laterally growing crystal grains as seed crystals and as a result, the grain boundary extends in the scanning direction of the laser beam and beltlike crystal grains grow.

In this way, the SLS method has demonstrated the possibility of one-dimensional control of the grain boundary position. Unfortunately, however, this method is only a method of one-dimensional control, and the space of the grain boundary, i.e. the width of the crystal grain must be widely distributed, because beltlike crystal grains originate from random crystal grains in both the position and grain diameter of the crystal grain formed in the first shot, and the randomness has an influence all the way to the end of lateral growth. The randomness of this origin also causes meandering, collision and divergence of the grain boundaries to impair controllability in one-dimensional control.

For compensating for such uncertainty with the SLS method and making improvements, Japanese Patent No. 03204986 describes an idea of using the method of grain filtering growth of a single seed crystal with a patterned amorphous silicon thin film (H. J. Song and J. S. Im, Appl. Phys. Lett. Vol. 68, 3165 (1996)) in combination with the SLS method.

In this idea of using the two methods in combination, an amorphous silicon thin film is patterned into an isolated island-like pattern consisting of a small region including a light-shielded portion, a narrow bridge region connected to the small region, and a main region connected to the other end of the bridge region, and laser beam irradiation by SLS is carried out in this order.

In the first shot, amorphous silicon in the light-shielded portion of the small region is not completely molten but becomes a fine polycrystal group, while its surrounding non-specific region is completely molten, and therefore a large number of crystal grains grow in its periphery using the former as seed crystals. In the second and subsequent shots, the crystal grains further grow in the lateral direction, but the lateral growth is limited by the island-shaped pattern of the amorphous silicon thin film and thus propagated only to the bridge region. Because the bridge region is narrow, crystal grains that can be propagated through the bridge region by lateral growth are subjected to grain filtering. Crystallization of the main region by SLS proceeds using grain crystals grain-filtered in the subsequent shots as seed grains.

Here, if a single crystal grain grows in the light-shielded portion of the small region, or only a single crystal grain can be reliably grain-filtered in the bridge portion, the main region could become a single crystal grain comprised of continuous crystal grains. Actually, however, it is very difficult to have only a single crystal grain unmelted in the thin film by a method of providing a temperature distribution in the surface of the thin film as in the former, while the width of the bridge should be reduced unlimitedly for increasing the yield of the single crystal grain in grain filtering of the propagated crystal grain as in the latter, and thus there arises difficulty in terms of a microfabricating technique.

The problem to be solved by the present invention is to realize a new process for highly two-dimensionally controlling the positions of crystal grains and grain boundaries in a process for producing a crystalline thin film using the scanning type melting recrystallization (ZMR) method and the SLS method described above, provide a crystalline thin film having the crystal grain position highly controlled by the production process, and further provide a high-performance element, circuit and device using the thin film.

### DISCLOSURE OF THE INVENTION

The present invention relates to a process for producing a crystalline thin film by melting and resolidifying a thin film, and is characterized by comprising the steps of:

(A) preparing a thin film having a specific region arranged at a predetermined position, the specific region being continuous to a surrounding non-specific region and different in melting or resolidification property from the surrounding non-specific region;

(B) locally melting and resolidifying a partial area including the specific region in the thin film; and

(C) locally melting and resolidifying another partial area including a region that is not the specific region (hereinafter referred to as “non-specific region”) sharing a common boundary with an area crystallized by resolidification in a preceding step.

The method described above includes, as a preferable embodiment, an embodiment in which a region which is altered by melting of the starting thin film contacts only a surface that does not have a crystal structure continuous to a crystalline thin film after alteration. Here, “contacting only a surface that does not have a crystal structure continuous to a crystalline thin film” refers to, for example, an embodiment in which a starting thin film is deposited on an amorphous glass substrate, and means that none of areas that are altered by melting of the starting thin film contact the surface of a monocrystal substrate comprised of the same crystal grains as those constituting the crystalline thin film.

It is also a preferable process that the step (C) is repeated while the area to be locally molten is shifted in one direction, whereby the crystallized area is made to grow in the direction of shifting.

The step (B) may be a step in which the non-specific region is locally molten, and the molten area is continuously shifted and made to pass through the specific region, whereby the specific region is molten and resolidified.

It is also a preferable embodiment of the present invention that the step of (C) is carried out while the area to be molten is continuously shifted subsequently to the preceding step, and is repeated while the area to be locally molten is continuously shifted in one direction, whereby a crystallized area is made to grow in the direction of shifting.

It is also a preferable embodiment of the present invention that the step of (C) is a step in which the partial area is locally heated pulsewise, molten and resolidified, and the step (C) is repeated while the area to be locally molten is shifted stepwise in one direction, whereby a crystallized area is made to grow in the direction of shifting.

The present invention is a process for producing a crystalline thin film, characterized by providing a specific region in a thin film, locally melting a partial area of the thin film, and shifting the locally molten partial area and making the same to pass through the specific region.

The present invention is also a process for producing a crystalline thin film, wherein an area including a part of a boundary between the position-controlled crystal grain of a thin film and the surrounding region is made a melting-resolidified area, and the crystal grain is made to laterally grow through a melting-resolidification step in which the melting-resolidified area is locally heated pulsewise, molten and resolidified.

An element formed by using the crystalline thin film of the present invention, wherein the spatial position of at least a part of a crystal grain having a continuous crystal structure is determined by the spatial position of a specific region in a starting thin film, and the crystal grain having the controlled spatial position is used in an active region, and a circuit having a plurality of the elements connected one another by wires also constitute the present invention.

### BREIF DESCRIPTION OF THE DRAWINGS

FIGS. 1A, 1B, 1C, 1D, 1E, 1F, 1G, 1H and 1I are diagrams of production steps illustrating the first fundamental embodiment of a crystalline thin film and a method for producing the same according to the present invention;

FIGS. 2A, 2B, 2C, 2D, 2E, 2F, 2G, 2H and 2I are diagrams of production steps illustrating the second fundamental embodiment of the crystalline thin film and the method for producing the same according to the present invention;

FIG. 3 is a diagram illustrating one embodiment of an element, a circuit and an apparatus according to the present invention;

FIGS. 4A, 4B, 4C, 4D, 4E, 4F, 4G, 4H and 4I are diagrams of production steps illustrating the first fundamental embodiment of a crystalline thin film and a method for producing the same according to the present invention;

FIGS. 5A, 5B, 5C, 5D, 5E, 5F, 5G, 5H and 5I are diagrams of production steps illustrating the second fundamental embodiment of the crystalline thin film and the method for producing the same according to the present invention; and

FIGS. 6A, 6B, 6C, 6D, 6E and 6F are diagrams of production steps illustrating the embodiment of preparing a thin film having position-controlled crystal grains for use in the crystalline thin film and the method for producing the same according to the present invention.

### BEST MODE FOR CARRYING OUT THE INVENTION

The present invention is a process for producing a crystalline thin film by melting and resolidifying a thin film, comprising the steps of:

(A) preparing a thin film having a specific region arranged at a predetermined position, the specific region being continuous to a surrounding non-specific region and different in melting or solidification property from the surrounding non-specific region;

(B) locally melting and resolidifying a partial area including the specific region in the thin film; and

(C) locally melting and resolidifying a partial area including a non-specific region sharing a common boundary with an area crystallized by resolidification in a preceding step.

In the process described above, two processes can be considered. The first process is such that the step of (C) is carried out subsequent to the step of (B), the molten area of (B) is laterally shifted to resolidify a specific region, and at the same time the adjacent area is molten. For resolidifying the molten adjacent area, heating may be stopped at this time, or an area to be molten may be further shifted in the lateral direction.

The second process is such that after heating is temporarily stopped in the step of (B) to resolidify the specific region, a part of an area adjacent to the formed crystallized area (referred to also as crystal grains) is irradiated with a pulse laser beam again and molten and resolidified, in which steps of (B) and (C) are separated and stepwise carried out.

In any of the above processes, the crystallized area can be made to grow in the direction of shifting the area to be molten by repeating the step of (C) while shifting the area to be molten in one direction. The step of (C) is continuously repeated in the first process while the step of (C) is stepwise repeated intermittently in the second process. For heating/melting means, a continuous output laser is used in the first process, and a pulse output laser is used in the second process.

The first process and then the second process will be described below.

(First Method for Producing Crystalline Thin Film)

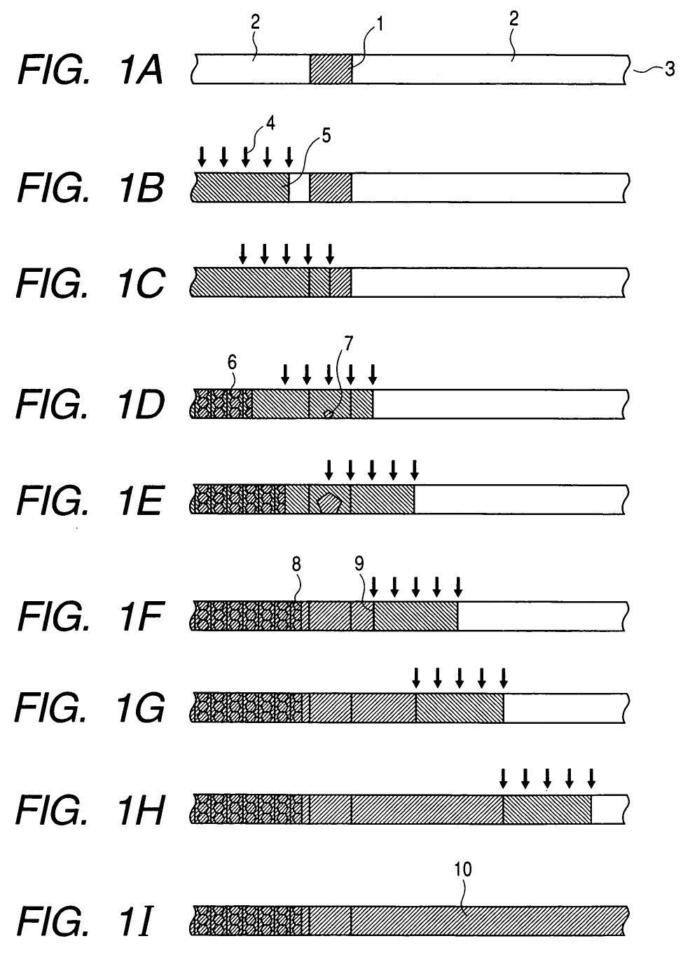

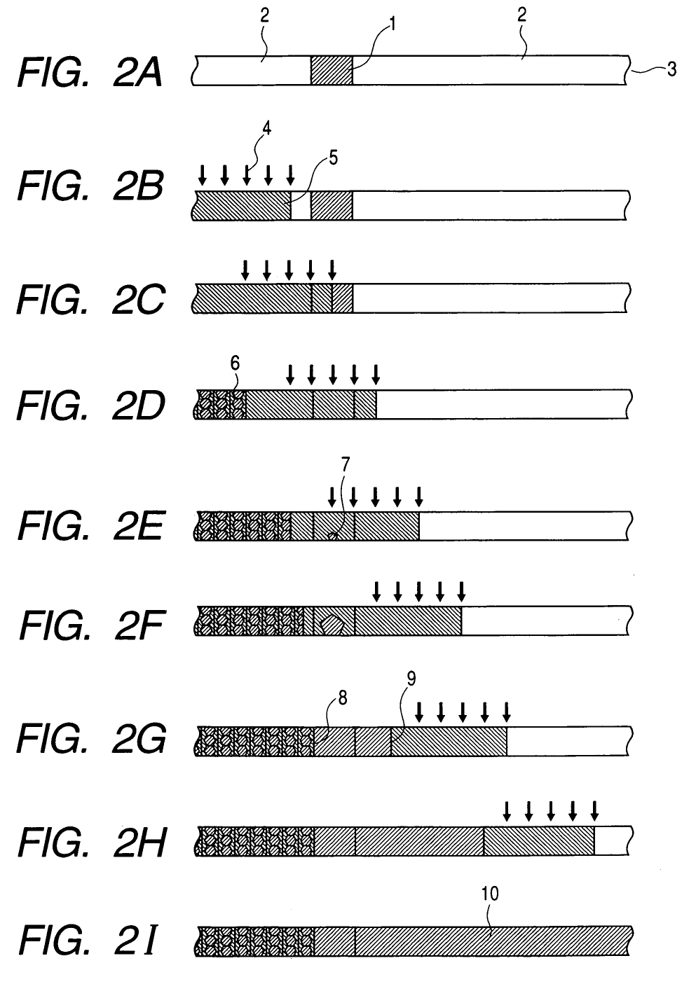

An example of the fundamental embodiment of a first method for producing a crystalline thin film according to the present invention will be described using FIGS. 1A to 1I. In these figures, the thin film is schematically shown by a cross section of a part of the thin film cut along a plane vertical to the surface or interface thereof and the scanning direction of a molten area. Furthermore, the thin film according to the present invention may contact other layers provided on and under the thin film but in FIGS. 1A to 1I, such layers are omitted and only the thin film is shown for the sake of convenience. In the figure, the thin film is schematically shown by the cross section of a part of the thin film cut along the plane vertical to the surface or interface thereof and the scanning direction of the molten area. Furthermore, the thin film according to the present invention may contact other layers provided on and under the thin film but in FIGS. 1A to 1I and 2A to 2I, the layers are not omitted for the sake of convenience, and only the thin film is shown.

In the figures, reference numeral 1 denotes a specific region, reference numeral 2 denotes surrounding non-specific regions of the specific region, reference numeral 3 denotes a starting thin film, reference numeral 4 denotes an energy deposited for melting, reference numeral 5 denotes a molten partial area, reference numeral 6 denotes a resolidified area with randomly formed crystal grains, reference numeral 7 denotes a position-controlled crystal grain or crystalline cluster, reference numeral 8 denotes a grain boundary due to collision of the position-controlled crystal grain and the randomly formed crystal grains, reference numeral 9 denotes a solid-liquid interface between the position-controlled crystal grain and the molten partial area, and reference numeral 10 denotes a position-controlled crystal grain.

Regarding the origin of crystal grains or crystalline clusters growing from a specific region, the process of producing the crystalline thin film according to the present invention can be classified broadly into the case where they are crystal grains or crystalline clusters remaining unmelted in the specific region when the starting thin film is molten and the case where they are crystal grains or crystalline clusters nucleated from a molten phase in a resolidification step after the specific region is molten.

The-most fundamental embodiments of the respective cases will be described using FIGS. 1A to 1I and 2A to 2I, respectively.

First, the case will be described where crystal grains or crystalline clusters growing from the specific region are crystal grains or crystalline clusters remaining unmelted in the specific region when the starting thin film is molten.

First, as shown in FIG. 1A, the specific region 1 and surrounding non-specific regions 2 of the specific region are provided in the thin film to form the starting thin film 3. Energy 4 deposited for the melting is locally deposited to a part of the surrounding non-specific region 2 of the specific region situated on the left side of the specific region 1 in the figure to melt the partial area 5 (FIG. 1B).

Then, the position of deposition of energy 4 deposited for the melting is shifted, whereby the molten partial area 5 is shifted toward the specific region 1 situated on the right side in the figure (FIG. 1C). At this time, the surrounding non-specific region 2 of the molten specific region is completely molten, and is therefore kept in a molten state for a while after energy 4 deposited for melting passes. Thereafter, when the supercooling increases, spontaneous nucleation in the molten phase explosively occurs, and the resolidified area 6 with randomly formed crystal grains is formed (FIG. 1D). The polycrystal structure of this resolidified area 6 with randomly formed crystal grains is essentially the same as that obtained by the conventional technique described above.

On the other hand, a desired number of crystal grains or crystalline clusters 7 remain unmelted in the specific region 1 having in its entire region a maximum melting state due to shift of the molten partial area 5 (FIG. 1D). Crystal grains or crystalline clusters 7 remaining unmelted in the specific region 1 suffer decrease in temperature at the same time and grow by further shift of the molten partial area 5 (FIG. 1E), while the resolidified area 6 with randomly formed crystal grains expands its region in the direction of shift of the molten partial area 5 (FIG. 1E).

Crystal grains or crystalline clusters 7 further growing with the shift of the molten partial area 5 reach the surface of the thin film, and then grow exclusively in the lateral direction of the thin film (FIG. 1F), but lateral growth in a direction opposite to the direction of shift of the molten partial area 5 eventually causes collision with the opposing resolidified area 6 with randomly formed crystal grains to form the grain boundary 8 (FIG. 1F). On the other hand, since the solid-liquid interface 9 always exists in the direction of shift of the molten partial area 5, the solid-liquid interface 9 shifts as if it flowed the shift of the molten partial area 5, and crystal grains or crystalline clusters 7 continuously grow (FIGS. 1G and 1H).

As a result, the crystal grain 10 position-controlled by originating from the vicinity of the specific region 1 and laterally growing in the direction of shift of the molten partial area 5 is obtained (FIG. 1I).

In the embodiment of the present invention illustrated in FIGS. 1A to 1I, the molten partial area 5 starts from the surrounding non-specific region 2 of the specific region at a certain time, passes through the specific region 1, and shifts to the surrounding non-specific region 2, but the molten partial area 5 may be started at a position including the specific region 1.

In the embodiment of the present invention illustrated in FIGS. 1A to 1I, an example in which one specific region 1 is provided in a sectional view is shown, but a plurality of similar specific regions may be provided in a space where the starting thin film extends in a direction vertical to the cross section. If a plurality of specific regions I each from which a single crystal grain grows are spaced uniformly in a direction perpendicular to the cross section of FIGS. 1A to 1I, crystal grain groups having almost equal widths extend in line in the direction of shift of the molten partial area 5 when viewed from the plane of the crystalline thin film after melting-resolidification.

In addition, a plurality of such specific regions 1 may be provided in the direction of shift of the molten partial area 5. In this case, the size of the position-controlled crystal grain 10 in the direction of shift of the molten partial area 5 is confined within limits up to near the next specific region 1, and there the position of the grain boundary is determined.

As described above, the specific region 1 and the surrounding non-specific region 2 of FIGS. 1A to 1I must be subjected to incomplete melting (or near-complete melting, which refers to incomplete melting near complete melting) and complete melting, respectively, for energy deposited 4 for melting. For this purpose, the relation of “accumulated energy density of specific region 1<critical energy density of specific region 1” and “accumulated energy density of surrounding non-specific region 2≧critical energy density for complete melting of surrounding non-specific region” should be required. Here, if the relation of “accumulated energy density of specific region 1≧accumulated energy density of surrounding non-specific region 2” is present, at least the relation of “critical energy density for complete melting of specific region 1>critical energy density for complete melting of surrounding non-specific region” must be obtained. In the present invention, various methods for this purpose are disclosed as describe below.

The first method is such that the specific region 1 and the surrounding non-specific region 2 are provided so that the specific region 1 includes crystal grains or crystalline clusters, and the relation of “concentration of crystal grains or crystalline clusters in specific region 1>concentration of crystal grains or crystalline clusters in surrounding non-specific region 2” or “average size of crystal grains or crystalline clusters in specific region 1>average size of crystal grains or crystalline clusters in surrounding non-specific region 2” is satisfied. For example, the surrounding non-specific region 2 should be a completely amorphous material, and the specific region 1 should be an amorphous material including crystal grains or crystalline clusters. Alternatively, the specific region 1 may be constituted by a single crystal grain having the same volume or more as thereof, while the surrounding non-specific region 2 may be a group of crystal grains each sufficiently smaller than the single crystal grain of the specific region 1.

The second method is such that the specific region 1 and the surrounding non-specific region 2 are provided so that the relation of “magnitude of free energy barrier to crystal nucleation in solid-phase crystallization of specific region 1<magnitude of free energy barrier to crystal nucleation in solid-phase crystallization of surrounding non-specific region 2” is satisfied. Even if the starting thin film 3 includes no crystal grain or crystalline cluster and is completely amorphous unlike the first method, nucleation occurs preferentially in the specific region 1 in the process of solid-phase crystallization which is generated immediately before melting of the starting thin film 3, and consequently the same situation as in conditions of the first method can be provided immediately before melting as long as the requirement about the free energy barrier to crystal nucleation described above is satisfied. The free energy barrier to crystal nucleation in solid-phase crystallization depends on properties such as the composition ratio, the impurity concentration, surface adsorbate, and the state of the interface with a substrate contacting the starting thin film, and a difference can be provided in magnitude of the free energy barrier to crystal nucleation by making the specific region 1 and the surrounding non-specific region 2 be different in any of these properties.

The third method is such that the specific region 1 and the surrounding non-specific region 2 are provided so that the relation of “thickness of specific region 1>thickness of surrounding non-specific region 2” is satisfied. The accumulated energy density decreases for the same absorption energy density as the thickness increases irrespective of whether or not the starting thin film 3 includes crystal grains or crystalline clusters, and therefore the method is effective. The thickness of the specific region 1 may increase for the surrounding non-specific region 2 in such a manner that it protrudes from any of two surfaces or both the surfaces of the starting thin film 3. In addition, the third method can be used in combination with the first or second method.

The fourth method is such that the relation of “rate of thermal draining from specific region>rate of thermal draining from surrounding non-specific region 2” is set when the rate of thermal draining from the thin film is sufficiently high. For example, when the starting thin film 3 contacts the substrate, both the regions can be made to have different thermal draining rates by making the heat resistance at the interface between the specific region 1 and the substrate less than the heat resistance at the interface between the surrounding non-specific region 2 and the substrate, or by embedding a member having a higher heat conductivity than its periphery in the substrate immediately under the specific region 1.

The fifth method is such that the absorption energy density is changed to meet the relation of “absorption energy density of specific region 1<absorption energy density of surrounding non-specific region 2”. For example, if the absorption coefficient of energy deposited of the specific region 1 is smaller than that of the surrounding non-specific region 2, this means can be directly used. Alternatively, if an energy 4 is deposited into the starting thin film 3 in the form of a beam, and a thin film serving as means for reflecting the energy or means for preventing reflection of the energy can be used, they may be provided on the surface of the specific region 1 or surrounding non-specific region thereof on the energy-deposited side.

Furthermore, as the sixth method, a direct method can be employed in which the deposited energy density itself is changed to meet the relation of “density of energy deposited into specific region 1<density of energy deposited into surrounding non-specific region 2”. For example, if deposited energy 4 can be modulated in intensity as it is scanned, the deposited energy may be reduced only when it passes through the specific region 1, and if the deposited energy 4 has a form of a beam, and partially transparent mask serving as means for reducing the energy can be used, this may be provided only on the specific region 1.

The case will now be described using FIGS. 2A to 2I where crystal grains or crystalline clusters growing from the specific region are crystal grains or crystalline clusters nucleated from a molten phase in resolidification after the specific region is molten.

First, as shown in FIG. 2A, the specific region 1 and surrounding non-specific regions 2 of the specific region are provided in the thin film to form the starting thin film 3. Energy deposited 4 for melting is locally deposited into a part of the surrounding non-specific region 2 of the specific region situated on the left side of the specific region 1 in the figure to melt the partial area 5 (FIG. 2B).

Then, the position of the deposited energy 4 for melting is shifted, whereby the molten partial area 5 is shifted toward the specific region 1 situated on the right side in the figure (FIG. 2C).

At this time, the surrounding non-specific region 2 of the molten specific region is completely molten, and is therefore kept in a molten state for a while after the deposited energy 4 for melting passes. Thereafter, when supercooling increases, spontaneous nucleation in the molten phase explosively occurs, and the resolidified area 6 with randomly formed crystal grains is formed (FIG. 2D). The polycrystal structure of this resolidified area 6 with randomly formed crystal grains is the same as that obtained by the conventional technique described above in terms of principle.

On the other hand,.the specific region 1 having in the entire region a maximally molten state due to shift of the molten partial area 5 is also completely molten (FIG. 2D). However, as soon as cooling starts due to further shift of the molten partial area 5, crystal grains or crystalline clusters 7 nucleated from the molten phase occur in the specific region 1 (FIG. 2E). Crystal grains or crystalline clusters 7 further grow (FIG. 2F) but on the other hand, the resolidified area 6 with randomly formed crystal grains expands its region in the direction of shift of the molten partial area 5 (FIG. 2F).

Crystal grains or crystalline clusters 7 further growing with the shift of the molten partial area 5 reach the surface of the thin film, and then grow exclusively in the lateral direction of the thin film (FIG. 2G), but lateral growth in a direction opposite to the direction of shift of the molten partial area 5 eventually causes collision with the opposing resolidified area 6 with randomly formed crystal grains to form the grain boundary 8 (FIG. 2G). On the other hand, since the solid-liquid interface 9 always exists in the direction of shift of the molten partial area 5, the solid-liquid interface 9 shifts as if it flowed the shift of the molten partial area 5, and crystal grains or crystalline clusters 7 continuously grow (FIG. 2H).

As a result, the crystal grain 10 position-controlled by originating from near the specific region 1 and lateral growth in the direction of shift of the molten partial area 5 is obtained (FIG. 2I). The relation between the spatial layout of the specific region 1 and the position-controlled crystal grain-bunch constituted by the crystal grain 10 is the same as described in FIGS. 1A to 1I.

As described above, the specific region 1 and the surrounding non-specific region 2 of FIGS. 2A to 2I are completely molten for energy deposited 4 for melting. That is, the accumulated energy densities of the specific region 1 and the surrounding non-specific region 2 are larger than the critical energy densities of the respective regions. For making nucleation of crystal grains or crystalline clusters 7 occur only in the specific region 1 preferentially, in the process of cooling after melting, a situation meeting the relation of “nucleation rate in specific region 1>>nucleation rate in the surrounding non-specific region 2” may be set. The nucleation rate J is proportional to an exponential function of a ratio between the crystal nucleus formation free energy barrier W* and the temperature T (J∝ exp (-W./kT), k: Boltzmann constant), and thus following two methods can be considered as methods for achieving the above situation.

The first method is such that the free energy barrier to crystal nucleation from the molten phase in resolidification of the specific region 1 is made to be lower than the free energy barrier to crystal nucleation from the molten phase in resolidification of the surrounding non-specific region 2. For providing a difference in free energy barrier to crystal nucleation between both the regions, the regions may be made to be different in any of composition ratio, impurity concentration, surface adsorbates, and the state of the interface with a substrate contacting the starting thin film.

The second method is such that the temperature of the specific region 1 is made to be lower than the temperature of the surrounding non-specific region 2 contacting the specific region 1 in the process of resolidification after at least the specific region 1 of the starting thin film is maximally molten. As described below, two types of means are available for realizing the method.

First means is means for meeting the relation of “rate of thermal draining from specific region>rate of thermal draining from surrounding non-specific region” if the rate of thermal draining from the thin film is sufficiently high. For example, if the starting thin film 3 contacts the substrate, both the regions can be made to have different thermal draining rates by making the heat resistance at the interface between the specific region 1 and the substrate less than the heat resistance at the interface between the surrounding non-specific region 2 and the substrate, or by embedding a member having a higher heat conductivity than its periphery in the substrate immediately under the specific region 1. Unlike the example described with FIGS. 1A to 1I, however, the accumulated energy density of the specific region 1 must also be greater than the critical energy density for complete melting.

Second means is such that the absorption energy density is changed to meet the relation of “absorption energy density of specific region 1<absorbed energy density of surrounding non-specific region 2”. Furthermore, as the sixth method, a direct method can be employed in which the deposited energy density itself is changed to meet the relation of “density of energy deposited into specific region 1<density of energy deposited into surrounding non-specific region 2”.

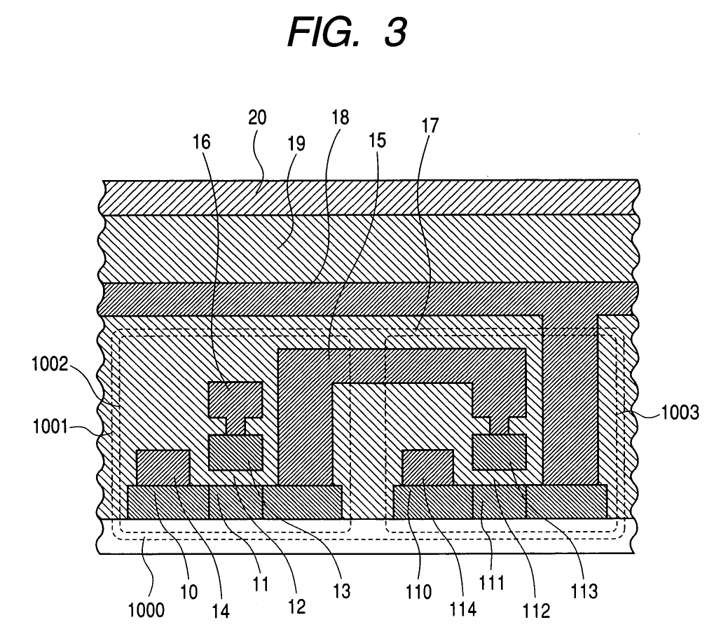

One typical example of the embodiment of an element, a circuit and a device of the present invention using the crystalline thin film formed by the melting-resolidification step described above will now be described using FIG. 3. FIG. 3 shows a partial cross section of an image displaying apparatus having a switching circuit having as a main component an MOS-type thin film transistor (TFT) provided in the crystalline thin film composed of a semiconductor material. Here, reference numeral 1001 denotes a range of a switching circuit, reference numerals 1002 and 1003 denote first and second TFTs, respectively, constituting the switching circuit 1001, reference numeral 1000 denotes a substrate, reference numerals 10 and 110 denote position-controlled crystal grains growing from a specific region corresponding to the region 10 of FIGS. 1A to 1I and 2A to 2I, reference numerals 11 and 111 denote gate regions formed in the crystal grains 10 and 110, reference numerals 12 and 112 denote gate insulating films, reference numerals 13 and 113 denote gate electrodes, reference numerals 14 and.114 denote source electrodes, reference numeral 15 denotes a drain electrode of the first TFT 1002 also serving as a gate electrode wire of the second TFT 1003 and electrode wire between the two TFTs, reference numeral 16 denotes a gate electrode wire of the first TFT 1002, reference numeral 17 denotes an inter-layer insulation layer, reference numeral 18 denotes a pixel electrode, reference numeral 19 denotes a light-emitting layer or light transmission control layer, and reference numeral 20 denotes an upper electrode. Crystal grains 10 and 110 can be formed by patterning some of crystal grains growing from a plurality of specific regions 1 in the steps shown in FIGS. 1A to 1I or FIGS. 2A to 2I.

In the crystalline thin film of the present * invention, the position and size of the crystal grain 10 is determined by the position at which the specific region 1 is provided and the direction and distance of shift of the molten partial area, and known. Thus, in formation of an element having the crystal grain 10 as an active region, the active region of the element using the crystal grain 10 can easily be related to the position of the crystal grain 10. That is, as illustrated in FIG. 3, the gate region 11 that is an active region of the TFT 1002 being the element of this device can be confined within the crystal grain 10. In this case, because no grain boundary is included in the active region of the TFT 1002, not only element characteristics are improved, but also fluctuation among a plurality of elements can be inhibited.

In the switching circuit of FIG. 3, the drain electrode 15 of the first TFT 1002 controlled by the gate electrode 13 is connected through a wire to the gate electrode 113 of the second TFT 1003, and the electrodes and wires are insulated from one another by the interlayered insulating layer 17. That is, the second TFT 1003 controlled by the gate electrode 113 is controlled by a drain voltage of the first TFT 1001. In this circuit, it is necessary that the element characteristics of the first and second TFTs should be accurately controlled, and this circuit constituted by elements having no grain boundary in the active region can meet this requirement.

In the image displaying apparatus of FIG. 3, a voltage applied to or a current introduced into the light-emitting layer or light transmission control layer 19 by the pixel electrode 18 or upper electrode 20 is determined by a drain voltage or current of the second TFT 1003 controlled by the drain voltage of the first TFT 1002. The light emission intensity or light transmittance of the light-emitting layer or light transmission control layer 19 is controlled by a voltage applied to the layer or a current introduced into the layer. The image displaying apparatus of this embodiment uses such an element configuration as a display unit of one pixel and has a plurality of the display units arranged in the form of a lattice. For obtaining a uniform light intensity and time response as image displaying apparatus, it is necessary that fluctuation in characteristics among pixels should be inhibited, and this apparatus using a circuit having elements including no grain boundary in the active region can meet the above requirement.

(Second Method for Producing Crystalline Thin Film)

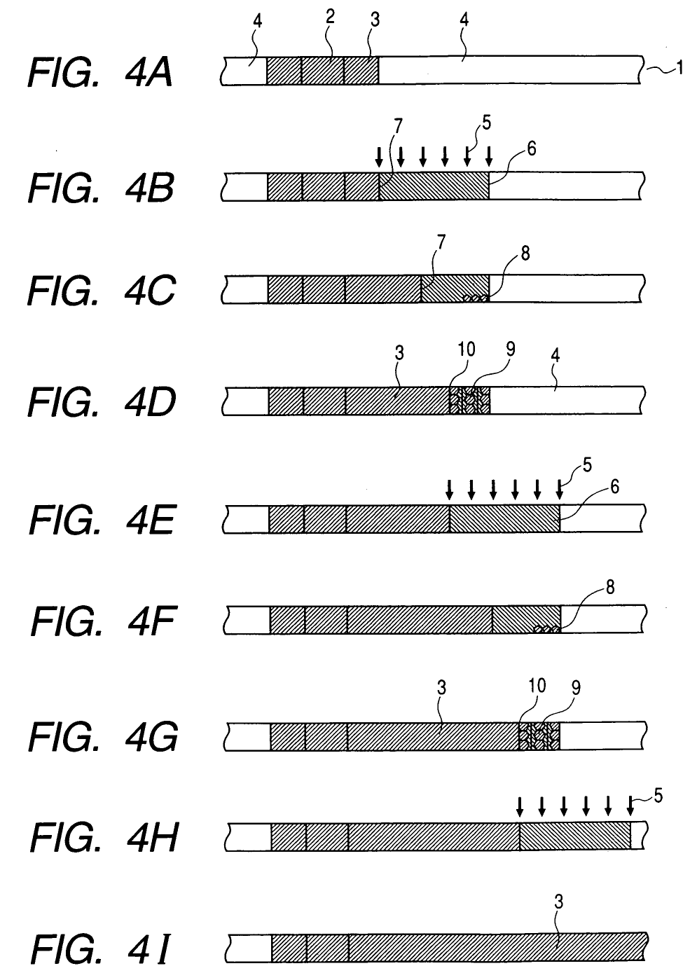

An example of the fundamental embodiment of a second method for producing a crystalline thin film according to the present invention will be described using FIGS. 4A to 4I, 5A to 5I and 6A to 6F. In these figures, the thin film is schematically shown by a cross section of a part of the thin film cut along a plane vertical to the surface or interface thereof and the scanning direction of a molten area. Furthermore, the thin film according to the present invention may contact other layers provided on and under the thin film but in FIGS. 4A to 4I, 5A to 5I and 6A to 6F, such layers are omitted and only the thin film is shown for the sake of convenience. In these figures, reference numeral 1 denotes a thin film, reference numeral 2 denotes a specific region, reference numeral 3 denotes a position-controlled crystal grain, reference numeral 4 denotes a region that is not yet a melting-resolidified area (hereinafter referred to as “unmelted region”), reference numeral 5 denotes local pulse heating means for melting of the thin film 1, reference numeral 6 denotes a molten area in which a melting-resolidified area being an area including a part of the boundary between the position-controlled crystal grain 3 and the surrounding non-specific region is in a molten state, reference numeral 7 denotes a solid-liquid interface situated at the boundary between the position-controlled crystal grain 3 and the melting-resolidified area in the molten state, reference numeral 8 denotes a crystal grain randomly nucleated from a molten phase (hereinafter abbreviated as “nucleated crystal grain”), reference numeral 9 denotes a fine crystal resolidified area formed by solidification of the nucleated crystal grains 8 randomly nucleated from the molten phase, and reference numeral 10 denotes a grain boundary between the crystal grain 3 and the fine crystal resolidified area 9. Furthermore, the crystal grain 3 denoted by reference numeral 3 also represents a crystal grain grown laterally from the position-controlled crystal grain (crystal grain having a crystal structure continuous to the position-controlled crystal grain). In addition, the surrounding non-specific region of the crystal grain 3 is, for example, the unmelted region 4 in FIG. 4A and the region including the unmelted region 4 and the fine crystal resolidified area 9 in FIG. 4D, and thus may be denoted by reference numeral 4, or 4, 9 or the like in the following. Furthermore, the overall molten area 6 molten by the pulse heating means 5 is an area that subsequently becomes a melting-resolidified area, and thus the melting-resolidified area may be denoted by reference numeral 6.

First, as shown in FIG. 4A, the thin film 1 having the crystal grain 3 and the surrounding non-specific region 4 controlled at the position of the specific region 2 is prepared. Here, by applying local pulse heating means 5 to the thin film 1, an area including a part of the boundary between the position-controlled crystal grain 3 and the surrounding non-specific region 4 is molten, and formed as the melting-resolidified area 6 (FIG. 4B). The solid-liquid interface 7 generated at the boundary between the position-controlled crystal grain 3 and the melting-resolidified area 6 molten shifts from the solid side of the solid-liquid interface 7 to the liquid phase side thereof as the cooling of the molten area 6 proceeds after the stop of the local pulse heating means 5 (FIG. 4C). Consequently, the position-controlled crystal grain 3 grows laterally to promote resolidification of the molten area 6. On the other hand, when the supercooling of the molten area 6 which is still in the molten state increases, the randomly nucleated crystal grains 8 occur at a high rate and in high density there due to spontaneous nucleation in the molten phase (FIG. 4C) and the fine crystal resolidified area 9 is formed (FIG. 4D). Shift of the solid-liquid interface 7 is blocked by the fine crystal resolidified area 9, the grain boundary 10 (grain boundary of the crystal grain having a crystal structure continuous to the position-controlled crystal grain) is formed there, and resolidification is completed just when lateral growth of the position-controlled crystal grain 3 stops (FIG. 4D).

Steps of FIGS. 4A to 4D described above constitute the most fundamental part of the method for producing the crystalline thin film according to the present invention. In this way, the crystal grain 3 controlled to be at the position of the specific region 2 has grown laterally from the size of FIG. 4A to the size of FIG. 4D. If the size of FIG. 4D meets the application of the crystalline thin film, the process is completed with the one time melting-resolidification step. If a larger size is required, the melting-resolidified area 6 may be shifted to carry out in the same steps as the steps of FIGS. 4A to 4D again as shown in FIG. 4E and the subsequent figures. Specifically, the crystal grain 3 of FIG. 4D that laterally grew once is defined as the crystal grain 3 controlled to be at the position of the specific region 2, the unmelted region 4, the fine crystal resolidified area 9 and an area including a part of the grain boundary 10 are defined as a new melting-resolidified area 6, and this part is molten again by the local pulse heating means 5 (FIG. 4E). As a result, through the same melting-resolidification step as that of the first step (FIG. 4F), the position-controlled crystal grain 3 can extend the lateral growth distance (FIG. 4G). If it is desired that the lateral growth distance should be further extended, the same step may be repeated while the sequential melting-resolidified area 6 is shifted (FIG. 4H). In this way, a crystalline thin film including the position-controlled crystal grain 3 having a desired lateral growth distance can be produced (FIG. 4I).

In the embodiment of the present invention illustrated in FIGS. 4A to 4I, an example in which one crystal grain 3 position-controlled to be in the specific region 2 is provided in the sectional view is shown, but a plurality of similar specific regions and crystal grains may be provided in a space where the starting thin film expands in a direction vertical to the section. That is, if a plurality of sets of specific regions 2 and crystal grains 3 are spaced uniformly in a direction vertical to the section of FIGS. 4A to 4I, crystal grains each having almost the same width extend in line in the direction of shift of the melting-resolidified area 6 when viewed from the plane of the crystalline thin film after melting-resolidification. In addition, a plurality of such sets of specific regions 2 and crystal grains 3 may be provided in the direction of shift of the melting-resolidified area 6. In this case, the lateral growth distance of the position-controlled crystal grain 3 is confined within limits up to near the next set of the specific region 2 and the crystal grain 3, and the position of the grain boundary is defined here.

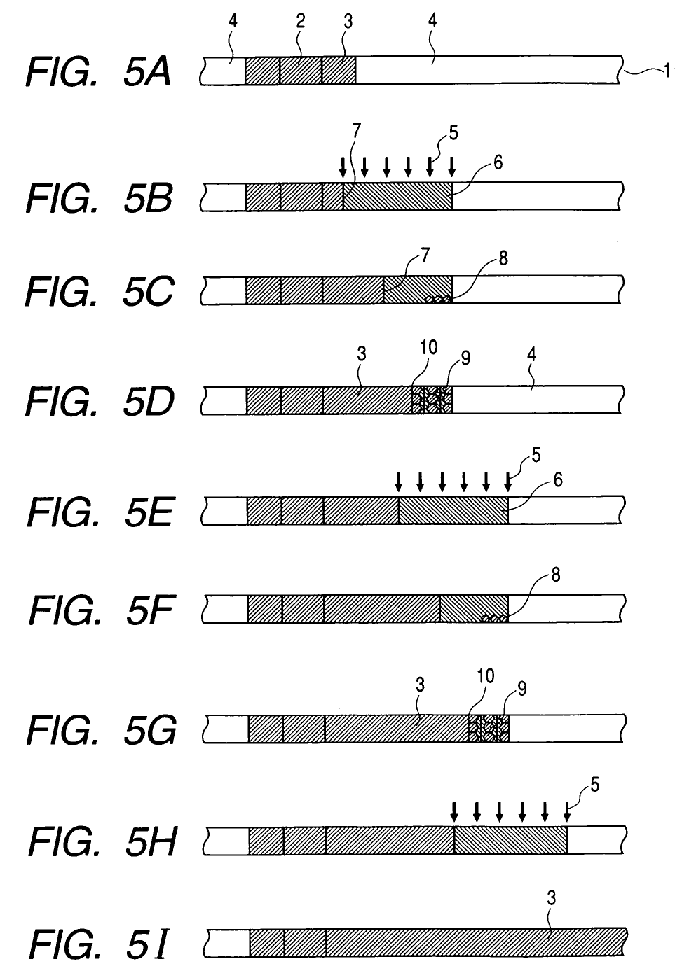

In the embodiment of the present invention illustrated in FIGS. 4A to 4I, the example is shown in which one end of the melting-resolidified area 6 is necessarily situated at the boundary between the position-controlled crystal grain 3 and the surrounding non-specific region (which corresponds to the grain boundary 10 with the randomly formed fine crystal resolidified area 9 in the second melting-resolidification step), but the present invention is not limited to the example, and the melting-resolidified area 6 should only include this boundary. For example, as shown in FIGS. 5A to 5I, the melting-resolidified area 6 may include a part of the position-controlled crystal grain 3 across this boundary. However, it should not include the whole area of the crystal grain 3. If melting-resolidification is repeated stepwise, this embodiment is equivalent to the case where adjacent melting-resolidified areas 6 have a region overlapping each other as a step. The embodiment of FIGS. 4A to 4I and the embodiment of FIGS. 5A to 5I can be mixed in terms of principle.

The crystal grain 3 position-controlled with the specific region 2 of the thin film 1 shown in FIGS. 4A and 5A is preferably a single crystal grain having a continuous crystal structure. This preferable embodiment assures that the crystal grain 3 that subsequently grows laterally also maintains a continuous crystal structure. The method for providing in a precursor of the thin film 1 the specific region 2 and the single crystal grain 3 position-controlled to be in the specific region 2 can be classified broadly into two types.

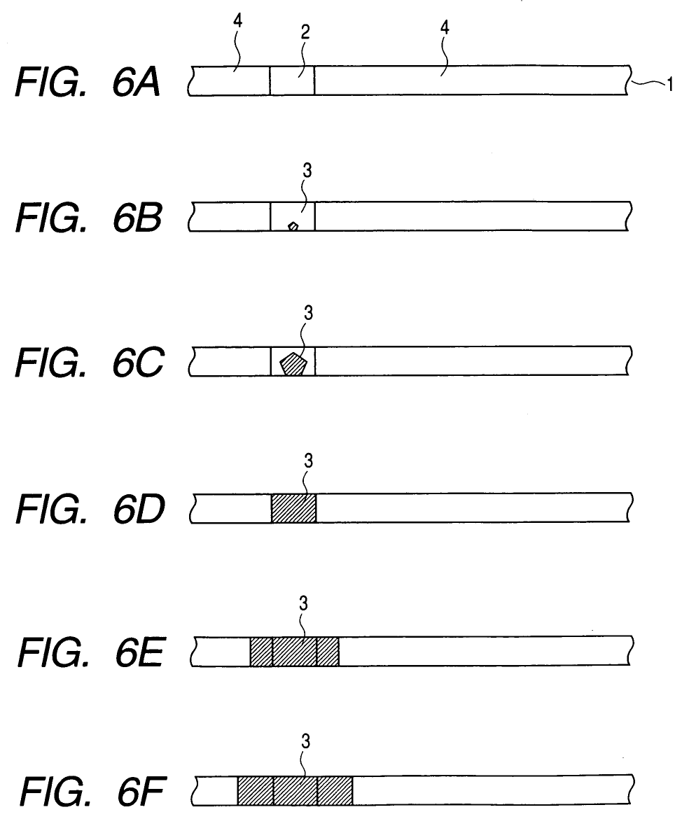

The first method is a method in which the precursor of the thin film 1 is an amorphous thin film, and the single crystal grain 3 is made to solid-phase grow in the specific region 2. That is, as shown in FIG. 6A, the specific region 2 is provided in the precursor of the thin film 1, and the entire thin film is isothermally annealed at a temperature equal to or lower than its melting point, whereby the crystal grain 3 is formed in the specific region 2 selectively and preferentially (FIG. 6B), solid-phase grows (FIG. 6C), fills up the specific region 2 (FIG. 6D). Then continues lateral growth across the specific region 2 (FIG. 6E), whereby the single crystal grain 3 can be provided at the position of the specific region 2 (FIG. 6F).

For position control of such selective and preferential solid-phase crystallization, the solid phase nucleation rate is increased to preferentially nucleate the single crystal grain 3 in the specific region 2 by using the aforementioned means or the like so that the magnitude of the free energy barrier to solid phase nucleation in the specific region 2 is smaller than that in the surrounding non-specific region 4 or the like, or for the density and size distribution of the crystalline clusters that may be included in the amorphous precursor, the density or size distribution of the specific region 2 is shifted to a higher density or a larger size compared to the surrounding non-specific region 4 so that the crystal grain 3 is made to grow preferentially in the specific region 2.

The second method is a method in which the single crystal grain 3 is made to grow in the specific region 2 by melting-resolidification of the precursor of the thin film 1. That is, when the specific region 2 is provided in the precursor of the thin film 1 and the thin film is molten as shown in FIG. 6A, the crystal grain 3 remains unmelted selectively in the specific region 2 at the maximum melting (FIG. 6B), or nucleation of the crystal grain 3 from the molten phase occurs preferentially in the specific region 2 during cooling after melting (FIG. 6B). The crystal grain 3 liquid-phase grows (FIG. 6C), fills up the specific region 2 (FIG. 6D), and then continues lateral growth across the specific region 2 (FIG. 6E), whereby the single crystal grain 3 can be provided at the position of the specific region 2 (FIG. 6F).

For position control of such selective and preferential crystallization by melting-resolidification, means similar to that of the first method can be used.

In the two types of methods, it is also possible to perform solid-phase crystallization or melting-resolidification from the state of FIG. 6B by forming the precursor of the thin film 1 after previously placing the crystal grain 3 on a substrate on which the precursor of the thin film 1 is formed. There is various means such as a selective deposition method for placing the crystal grain 3 at a position that should be the specific region 2.

As described above, in the present invention, a molten partial area of a starting thin film provided with a specific region passes through the specific region in a crystalline thin film that is formed by scanning type melting recrystallization, and position-controlled crystal grains are provided as seed crystals when crystals ate made to laterally grow by stepwise melting-resolidification, thereby easily achieving high level spatial position control of crystal grains and grain boundaries constituting the crystalline thin film.

By controlling the spatial position of the specific region, the spatial position of at least a part of the crystal grain having a continuous crystal structure in the crystalline thin film can be controlled.

For the crystalline thin film of the present invention, the controlled position of the crystal grain constituting the crystalline thin film is spatially related to the specific region of the element, or the specific region of the element is formed in the position-controlled single crystal grain, whereby the operation characteristics of the element can be significantly improved, and fluctuation thereof can be reduced compared to the case where the conventional crystalline thin film comprised of only randomly formed crystal grains is used.

Furthermore, for the circuit formed using the element of the present invention, the operation characteristics can be significantly improved and fluctuation thereof can be reduced compared to the circuit constituted by the element using the crystalline thin film comprised of only randomly formed crystal grains that are not position-controlled.

Furthermore, in the apparatus of the present invention including the element or circuit of the present invention, the operation characteristics can be significantly improved by improvement of the operation characteristics of the element or circuit and reduction of fluctuation. The apparatus of the present invention provides a high-performance apparatus which could not be achieved if using the crystalline thin film comprised of only randomly formed crystal grains that are not position-controlled.

The following Examples 1-1 to 1-14 are examples of the first method for producing a crystalline thin film according to the present invention.

### EXAMPLE 1-1

As first Example of the first method for producing a crystalline thin film, a first example of a crystalline silicon thin film formed in steps shown in FIGS. 1A to 1I will be described.

First, as a precursor, an amorphous silicon thin film with the thickness of 50 nm including crystalline silicon clusters was deposited on a fused quarts substrate as a substrate by low-pressure chemical vapor deposition. The surface of this amorphous silicon thin film was coated with a photoresist, and patterned by a photolithography step so that 1 μm square photoresist islands were left at intervals of 5 μm along a straight line. Silicon ions were injected from the surface using the photoresist islands as a mask under the conditions of acceleration energy of 25 keV and dose of 1×10¹⁵ cm². Thereafter, the photoresist islands as a mask were removed, and the resultant thin film was used as a starting thin film. The crystallinity of this starting thin film was examined, and as a result, no change in the amorphous silicon thin film including crystalline silicon clusters was found in the 1 Am square regions aligned along a straight line at intervals of 5 μm, provided with the photoresist island mask, while in other regions having silicon ions injected therein, no crystalline silicon clusters were observed, and they were completely amorphous within the scope of the observation.

Then, secondary harmonic light (wavelength: 532 nm) of a continuous oscillation Nd: YVO 3 solid laser of laser diode excitation was formed into a spot having a width of 20 μm and a length of 400 μm, and this laser beam was applied to the starting thin film while scanning along the width direction of the spot of the laser beam at a scanning rate of 200 mms⁻¹. In application of the laser beam, the longitudinal direction of the spot was made to match the direction in which the 1 μm square regions of the starting thin film provided with the photoresist island mask were aligned along a straight line at intervals of 5 μm. In addition, scanning of the laser beam was started at a position 100 μm before the straight line along which the 1 μm square regions of the starting thin film provided with the photoresist island mask were aligned at intervals of 5 μm, and finished after scanning over 200 μm therefrom to obtain a crystalline thin film.

Observation of the obtained crystalline thin film showed that only a square region of about 200 μm×400 μm scanned with the laser beam was crystallized. This crystallized area had two separate regions each of about 100 μm×400 μm, and the boundary between these regions was situated on the straight line along which the 1 μm square regions of the starting thin film provided with the photoresist island mask were aligned at intervals of 5 μm, and which were parallel to the longitudinal direction of the laser beam spot. Further detailed observation of the crystal grain structure on the laser beam scanning start side of this boundary showed that the direction of a main component of the grain boundary matched the laser beam scanning direction, but the anisotropy was weak, the grain boundary repeatedly collided and diverged, and the pitches of the grain boundaries were widely distributed around the mean value of 1.5 μm. On the other hand, in the region after the laser beam passed through the boundary, uniformly spaced grain boundaries with the width of 5 μm were aligned in parallel to the scanning direction of the laser beam. In other words, it can be said that the region is filled up with 5 μm-wide and 100 μm-long crystal grains. These crystal grains converge to sequences of points on a straight line where they are aligned at intervals of 5 μm at near the boundary, and it can thus be considered that the crystal grains laterally grew from the 1 μm square regions provided with the photoresist island mask in the starting thin film with the scanning of the laser beam.

In the starting thin film of this Example, the 1 μm square region masked with the photoresist island is greater in the mean value of the size distribution and the concentration of the crystalline clusters than the surrounding non-specific region having silicon ions injected therein, and these regions correspond to the specific region 1 and the surrounding non-specific region 2 in FIGS. 1A to 1I, respectively. In addition, in the crystalline thin film after melting-resolidification, the 5 μm-wide and 100 μm-long crystal grain laterally growing from the 1 μm square region masked with the photoresist island with the scanning of the laser beam corresponds to a position-controlled crystal grain 10 in FIGS. 1A to 1I, and crystal grains on the laser beam scanning start side of the boundary where 1 μm square regions masked with the photoresist island are aligned corresponds to a resolidified area 6 with randomly formed crystal grains in FIGS. 1A to 1I. In this connection, the melting-resolidification process with scanning of the same laser beam was observed over a certain time period for a thin film having silicon ions injected therein and a thin film having no silicon ions injected therein, and as a result, it was found that the former was completely molten while the latter was not completely molten.

That is, this Example is an example of producing a crystalline thin film, in which a starting thin film having as specific regions 1 μm square regions masked with photoresist islands contact only the surface of a fused quarts substrate having no crystal structure continuous to the crystalline thin film, a partial area of the starting thin film is locally molten by a laser beam spot, the locally molten partial area is continuously shifted and made to pass the specific region by scanning of the laser beam spot, wherein the starting thin film in which the crystal grain or crystalline cluster density (finite) of the specific region is greater than the crystal grain or crystalline cluster density (0) of its surrounding non-specific region, and the mean size (finite) of crystal grains or crystalline clusters of the specific region is greater than the mean size (0) of crystal grains or crystalline clusters of its surrounding non-specific region, so that the critical energy density for complete melting of the specific region is greater than the critical energy density for complete melting of its surrounding non-specific region, is irradiated with a laser beam providing an accumulated energy density smaller than the critical energy density for complete melting of the specific region and greater than the critical energy density for complete melting of its surrounding non-specific region, whereby a crystal grain or crystalline cluster remains unmelted in the specific region, and a desired number (1) of crystal grains or crystalline clusters grows from the specific region utilizing the unmelted crystal grain or crystalline cluster as a seed crystal and as a result, the spatial position of the specific region is controlled, whereby the spatial position of at least a part of the crystal grain having a continuous crystal structure in the crystalline thin film is controlled.

### EXAMPLE 1-2

As second Example, a second example of a crystalline silicon thin film formed according to the steps shown in FIGS. 1A to 1I will be described.

First, as a precursor, a hydrogenated amorphous silicon thin film with the thickness of 100 nm including no crystalline silicon clusters was deposited on a glass substrate having an amorphous silicon oxide surface as a substrate by plasma chemical vapor deposition, and subjected to dehydrogenation processing by a thermal treatment. An amorphous silicon oxide film with the thickness of 150 nm was deposited on the amorphous silicon thin film surface by a sputtering process, and patterned so that 1 μm square amorphous silicon oxide islands were left on 10 μm×50 μm rectangular lattice points by a photolithography step. Silicon ions were injected from the surface using the amorphous silicon oxide islands as a mask under the conditions of acceleration energy of 40 keV and dose of 2×10¹⁵ cm⁻², and then the amorphous silicon oxide islands as a mask were removed. Then, the amorphous silicon thin film was irradiated with KrF excimer laser light outputting pulse light with the half-value width of 30 ns at an energy density of 400 mJ·cm⁻² and molten and resolidified, and the resultant thin film was used as a starting thin film. In this starting thin film, a single crystal grain having a grain diameter of about 1.5 μm grew on each of the 10 μm×50 μm rectangular lattice points provided with the mask of the 1 μm square amorphous silicon oxide islands, and its periphery was filled randomly with fine crystal grains with the average grain diameter of about 50 nm.

Then, secondary harmonic light (wavelength: 532 nm) of a continuous oscillation Nd: YVO 3 solid laser of laser diode excitation was formed into a spot with the width of 10 μm and the length of 500 μm, and this laser beam was applied to the starting thin film while scanning in the width direction of the spot at a scanning rate of 50 mms⁻¹. In application of the laser beam, the longitudinal direction of the spot was made to match the direction of the short axis of the 10 μm×50 μm rectangular lattice points of the starting thin film where each single crystal grain with the grain diameter of about 1.5 μm was aligned. In addition, a step of starting the continuous scanning of the laser beam at an end of the starting thin film on the substrate, finishing first scanning after reaching the other end, and subsequently starting next scanning at-a position shifted by 500 μm from the scanning direction in the vertical direction was repeated, whereby the entire region of the starting thin film was molten and resolidified to obtain a crystalline thin film.

Observation of the obtained crystalline thin film showed that the entire region of the thin film was filled up with crystal grains that were 10 μm-wide and 50 μm-long on average, and they were arranged in the form of a rectangular lattice. Detailed observation of those crystal grains showed that they had a chevron shape having a raised portion and a recessed portion at both ends in a 50 μm length direction, respectively, rather than a rectangular shape. Furthermore, an apparently trace of the 1 μm square amorphous silicon oxide island used for injection of mask ions was observed in the raised portion of the chevron shape. On the other hand, in the step of forming the staring thin film of this Example, an amorphous silicon thin film having silicon ions injected therein and an amorphous silicon thin film having no silicon ions injected therein were prepared, and the melting-resolidification process when scanning secondary harmonic light of the Nd: YVO 3 solid laser under the conditions described above for the amorphous silicon thin films irradiated with KrF excimer laser light, respectively, under the conditions described above was observed and as a result, it was found that the former was completely molten and the latter was incompletely molten. With these facts considered comprehensively, it can be thought that each of the chevron-shaped crystal grains constituting the crystalline thin film of this Example used as a seed crystal, a crystal grain remaining unmelted from a single crystal grain with the grain diameter of about 1.5 μm in the 10 μm×50 μm rectangular lattice point of the starting thin film, and laterally grew from the seed crystal with scanning of the laser beam. Thus, it can be said that the average grain diameter (1.5 μm) of the region of the single crystal grain with the grain diameter of about 1.5 μm in the 10 μm×50 μm rectangular lattice points of the starting thin film is greater than the average grain diameter (50 nm) of the surrounding non-specific region, and the regions constitute the specific region 1 and the surrounding non-specific region 2, respectively, in FIGS. 1A to 1I.

That is, this Example is an example different from Example 1-1 in that the average size (1.5 μm) of crystal grains or crystalline clusters of the specific region is greater than the average size (50 nm) of crystal grains or crystalline clusters of the surrounding non-specific region, so that the critical energy density for complete melting of the specific region is greater than the critical energy density for complete melting of the surrounding non-specific region.

### EXAMPLE 1-3

As third Example, a third example of a crystalline silicon thin film formed according to the steps of FIGS. 1A to 1I will be described.

First, a silicon oxide film with the thickness of 1 μm was deposited on a SUS substrate to form a substrate. The same precursor as that of Example 1-2 was formed in the thickness of 50 nm on the substrate, and the same mask ion injection step as that of Example 1-2 was carried out, and the resultant film was used as a starting thin film.

Then, this starting thin film was irradiated with a laser beam in the same manner as in Example 1-2 except that only the scanning rate of the laser beam was increased to 100 mms⁻¹.

The shape of crystal grains constituting the obtained crystalline thin film was almost the same as that of the crystalline thin film of Example 1-2.

In the starting thin film of this Example, the 1 μm square region masked with the amorphous silicon oxide island and the other region were both amorphous, and had no crystalline clusters. However, the same starting thin film was isothermally annealed in the atmosphere of nitrogen at 600° C., and it was found that solid phase crystallization started preferentially in the 1 μm square region masked with the amorphous silicon oxide island. This shows that the free energy barrier to crystal nucleation in solid crystallization in the 1 μm square region masked with the amorphous silicon oxide island is lower than that in the surrounding non-specific region. For the cause of this, it can be considered that injection of silicon ions with acceleration energy of 40 keV reaching near the interface between the starting thin film and the substrate changed the state of the interface with the substrate contacting the starting thin film. In addition, for a thin film having silicon ions injected therein and a thin film having no silicon ions injected therein, the melting-resolidification process by scanning of the same laser beam was observed over a certain time period and as a result, it was found that the former was completely molten while the latter was incompletely molten. From these facts, it can be said that in this Example, the 1 μm square region masked with the amorphous silicon oxide island and the other region constitute the specific region 1 and the surrounding non-specific region 2, respectively, in FIGS. 1A to That is, this Example is an example different from Example 1-1 in that the state of the interface with the substrate contacting the starting thin film varies between the inside and outside of the specific region, so that the free energy barrier to nucleation to crystallite in solid phase crystallization of the specific region is lower than the free energy barrier to nucleation to crystallite in solid phase crystallization of the surrounding non-specific region and as a result, the critical energy density for complete melting of the specific region is greater than the critical energy density for complete melting of the surrounding non-specific region.

### EXAMPLE 1-4

As fourth Example, a fourth example of a crystalline silicon thin film formed according to the steps shown in FIGS. 1A to 1I will be described.

First, as a substrate, a plastic film coated with a silicon oxide film having a thickness of 2 μm was prepared, and an amorphous silicon thin film having a thickness of 50 nm was deposited as a precursor on the surface of the coated plastic film by vacuum deposition. Then, using a focused ion beam imaging process, bivalent tin ions were injected into 0.5 μm square regions aligned on a straight line at intervals of 5 μm under conditions of acceleration energy of 110 keV and dose of 1×10¹⁵ cm⁻², and the resultant film was used as a starting thin film. That is, in the starting thin film of this Example, tin as an impurity for silicon exists in only those regions.

Then, this starting thin film was irradiated with a laser beam in the same manner as in Example 1-1, and the obtained crystalline thin film was almost the same as that of Example 1-1 in shape of crystal grains constituting the crystalline thin film.

Local elemental analysis was performed for the obtained crystalline thin film and as a result, concentrated tin was detected at and around points spaced at intervals of 5 μm where 5 μm-wide and 100 μm-long crystal grains extending from the boundary in the laser beam scanning direction converged near the boundary. It is no doubt that these locations where tin was detected correspond to tin-injected 0.5 μm square regions aligned on a straight line at intervals of 5 μm in the starting thin film. On the other hand, the same starting thin film was isothermally annealed in the atmosphere of nitrogen at 600° C. and as a result, it was found that solid phase crystallization was started preferentially in the 0.5 μm square region having tin injected therein. Furthermore, for a thin film having tin injected therein and a thin film having no tin injected therein, the melting-resolidification process by scanning of the same laser beam was observed and as a result, it was found that the former was incompletely molten while the latter was completely molten. From the fact described above, it-is determined that the 5 μm-wide and 100 μm-long crystal grain position-controlled in this Example is formed by remaining a crystal grains preferentially nucleated in the solid phase in tin-injected 0.5 μm square regions aligned on a straight line at intervals of 5 μm unmelted during the melting process and by using the unmelted crystal grain as a seed crystal, whereby the crystal grain laterally grows with scanning of the laser beam. The tin-injected 0.5 μm square region and the other region corresponds to the specific region 1 and the surrounding non-specific region 2, respectively, in FIGS. 1A to 1I.

That is, this Example is an example different from Example 1-1 in that the concentration of impurity contained in the specific region (tin: finite) is different from the concentration of impurity contained in the surrounding non-specific region (tin: below detection limit), so that the free energy barrier to crystal nucleation in solid phase crystallization of the specific region is lower than the free energy barrier to crystal nucleation in solid phase crystallization of the surrounding non-specific region and as a result, the critical energy density for complete melting of the specific region is greater than the critical energy density for complete melting of the surrounding non-specific region.

### EXAMPLE 1-5

As fifth Example, a fifth example of a crystalline silicon thin film formed according to the steps shown in FIGS. 1A to 1I will be described.

First, a substrate and a precursor same as those of Example 1-4 were prepared, and a photoresist mask was formed using the same step and pattern as in Example 1-1. Nickel was deposited thereon in several atomic layers by vapor deposition, and then a starting thin film with nickel surface-absorbed only on amorphous silicon thin films in 1 μm square regions aligned on a straight line at intervals of 5 μm was formed by a lift-off process for peeling a photoresist mask.

Then, this starting thin film was irradiated with a laser beam in the same manner as in Example 1-1 and as a result, the obtained crystalline thin film was almost the same as that of Example 1-1 in shape of crystal grains constituting the crystalline thin film.

In this Example, it was difficult to verify localization of nickel as an impurity in the obtained crystalline thin film unlike Example 1-4 probably because a small absolute amount of nickel surface-absorbed to a part of the starting thin film diffused into the thin film. However, in the same isothermal annealing experiment as in Example 1-4, preferential solid phase crystallization was observed in the 1 μm square region to which nickel surface-absorbed, and it can thus be considered that the 5 μm-wide and 100 μm-long crystal grain position-controlled by melting-resolidification has the region as a starting point. In addition, for a thin film having nickel deposited thereon and a thin film having no nickel deposited thereon, the melting-resolidification process by scanning of the same laser beam was observed and as a result, it was found that the former was incompletely molten while the latter was completely molten. From the fact described above, it is determined that the 5 μm-wide and 100 μm-long crystal grain position-controlled in this Example is formed by remaining crystal grain preferentially nucleated in the solid phase in nickel-deposited 1 μm square region aligned on a straight line at intervals of 5 μm unmelted during the melting process and using the unmelted crystal grain as a seed crystal, whereby the crystal grain laterally grows with scanning of the laser beam. The nickel-deposited 1 μm square region and the other region corresponds to the specific region 1 and the surrounding non-specific region 2, respectively, in FIGS. 1A to 1I.

That is, this Example is an example different from Example 1-1 in that the surface adsorbate in the specific region (having nickel) is different from the surface adsorbate in the surrounding non-specific region (having no nickel), so that the free energy barrier to crystal nucleation in solid phase crystallization of the specific region is lower than the free energy barrier to crystal nucleation in solid phase crystallization of the surrounding non-specific region and as a result, the critical energy density for complete melting of the specific region is greater than the critical energy density for complete melting of the surrounding non-specific region.

### EXAMPLE 1-6

As sixth Example, a sixth example of a crystalline silicon thin film formed according to the steps shown in FIGS. 1A to 1I will be described.

First, the same substrate and precursor as those of Example 1-3 were prepared, and by a photolithography step and a dry etching step, a starting thin film with the thickness of an amorphous silicon thin film reduced by 20% from the surface other than 1 μm square regions arranged on a 10 μm×50 μm rectangular lattice points. That is, the thickness of this starting thin film is 100 nm in the 1 μm square regions situated on the 10 μm×50 μm rectangular lattice point and 80 nm in regions other than the square regions.

Then, this starting thin film was irradiated with a laser beam in the same manner as in Example 1-3 and as a result, a crystalline thin film having almost the same shape of crystal grains as that of Example 1-3 was obtained.

The crystal grain structure of the crystalline thin film was observed and as a result, a region relatively raised in the direction of thickness of the thin film was found at the leading end of a raised portion of a chevron-shaped crystal grain that was 10 μm-wide and 50 μm-long on average. It is estimated that the raised region resulted from the fact the stereoscopic shape of the 1 μm square region having a larger thickness than peripheral regions, situated on the 10 μm-wide and 50 μm-long rectangular lattice point in the starting thin film was smoothed due to mass transfer in the process of melting-resolidification. In addition, for a thin film having a thickness of 100 nm and a thin film having a thickness of 80 nm, the melting-resolidification process by scanning of the same laser beam was observed over a certain time period and as a result, it was found that the former was incompletely molten while the latter was completely molten. It can be considered that the chevron-shaped crystal grains constituting the crystalline thin film of this Example were formed by using, as seed crystals, crystal grains remaining unmelted in the regions having a large thickness, and laterally growing from the seed crystals with scanning of the laser beam. Thus, it can be said that the 1 μm square region situated in the 10 μm x 50 μm rectangular lattice point and the surrounding non-specific region constitute the specific region 1 and the surrounding non-specific region 2, respectively, in FIGS. 1A to That is, this Example is an example different from Example 1-1 in that the thickness (100 nm) of the specific region is larger than the thickness (80 nm) of the surrounding non-specific region, so that the maximum value of the accumulated energy density for melting in the specific region is smaller than the critical energy density for complete melting of the specific region, and the maximum value of the accumulated energy density for melting in the surrounding non-specific region is greater than the critical energy density for complete melting of the surrounding non-specific region.

### EXAMPLE 1-7

As seventh Example, a seventh example of a crystalline silicon thin film formed according to the steps shown in FIGS. 1A to 1I will be described.

First, a silicon nitride thin film having a thickness of 10 nm, and then a silicon oxide film having a thickness of 1 μm were deposited on a monocrystal silicon substrate by plasma chemical vapor deposition, and a bowl-shaped dimple having a diameter of an upper face of 2 μm was formed on a 10 μm×50 μm rectangular lattice point of this silicon oxide film by a photolithography step and a wet etching step to form a substrate. The surface of the silicon nitride thin film was slightly exposed by about 50 nm in diameter on the bottom situated in the center of the bowl-shaped dimple. The same precursor as that of Example 1-3 was deposited on this substrate to form a starting thin film.

Then, this starting thin film was irradiated with a laser beam in the same manner as in Example 1-3 except that only the scanning rate of the laser beam was reduced to 70 mms⁻¹ and as a result, a crystalline thin film having almost the same shape of crystal grains as that of the crystalline thin film of Example 1-3 was obtained.

The obtained crystalline thin film was observed from the surface and as a result, a recessed region having an outer diameter of about 2 μm was found at the leading end of a raised portion of a chevron-shaped crystal grain that was 10 μm-wide and 50 μm-long on average. As a result of observation of the cross section of this portion, it was shown that the recessed region corresponded to the bowl-shaped dimple formed in the substrate of the starting thin film. On the other hand, in isothermal annealing of the same starting thin film in the atmosphere of nitrogen at 600° C, nucleation in the solid phase occurred only at random positions and times, no preferentiality in the bowl-shaped dimple portion was found. In addition, a test substrate provided on a monocrystal silicon substrate with only a silicon nitride thin film having a thickness 10 nm, and a test substrate provided further thereon with a silicon oxide film having a thickness of 1 μm were prepared, a precursor of this Example was deposited on each of the test substrates, the melting-resolidification process by scanning of the same laser beam observed over a certain time period and as a result, it was shown that the former was incompletely molten and the latter was completely molten, and that the ultimate maximum temperature of the former thin film was lower than the temperature of the latter by nearly 100° C. From these facts, it can be considered that the amorphous silicon thin film was thermally insulated by the monocrystal silicon substrate and the silicon oxide film having a sufficiently large thickness in regions around the bowl-shaped dimple, while the amorphous silicon substrate was thermally isolated by the monocrystal silicon substrate having a large heat conductivity and the amorphous silicon thin film and the silicon nitride thin film having a thickness of only 10 nm in the bottom of the bowl-shaped dimple, and from the latter region, the heat of the heated amorphous silicon thin film flowed to the monocrystal silicon substrate at a high rate, so that crystal grains or crystalline clusters crystallized in the solid phase remained unmelted there, and chevron-shaped crystal grains of 10 μm-wide and 50 μm-long on average were obtained by laterally growing with scanning of the laser beam while using the unmelted crystal grains or crystalline clusters as seed crystals. Thus, it can be said that the bowl-shaped dimple region situated in the 10 μm×50 μm rectangular lattice point and the surrounding non-specific region of the starting thin film constitutes the specific region 1 and the surrounding non-specific region 2, respectively, in FIGS. 1A to 1I.

That is, this Example is an example different from Example 1-1 in that the rate of thermal draining from the specific region is greater than the rate of thermal draining from the surrounding non-specific region, so that the maximum value of the accumulated energy density for melting in the specific region is smaller than the critical energy density for complete melting of the specific region, and the maximum value of the accumulated energy density for melting in the surrounding non-specific region is greater than the critical energy density for complete melting of the surrounding non-specific region.

### EXAMPLE 1-8

As eighth Example, an eighth example of a crystalline silicon thin film formed according to the steps shown in FIGS. 1A to 1I will be described.

First, the same substrate and precursor as those of Example 1-3 were prepared, and 1 μm square silicon oxide islands were placed thereon in the thickness of 150 nm in the 10 μm×50 μm rectangular lattice points by the same step as in Example 1-2 to form a starting thin film.

Then, this starting thin film with the silicon oxide islands remaining thereon was irradiated with a laser beam in the same manner as in Example 1-3 except that only the scanning rate of the laser beam was reduced to 80 mms⁻¹ and as a result, a crystalline thin film having almost the same shape of crystal grains as that of Example 1-3 was obtained.

Observation of the obtained crystalline thin film showed that the 1 μm square silicon oxide islands remained at the leading ends of raised portions of chevron-shaped crystal grains that were 10 μm-wide and 50 μm-long on average. In isothermal annealing of the same starting thin film in the atmosphere of nitrogen at 600° C., nucleation in the solid phase occurred only at random positions and times, and no preferentiality in the region under the 1 μm square silicon oxide was found. On the other hand, for a thin film provided on the entire surface with a silicon oxide thin film having a thickness of 150 nm and a thin film provided with no such a silicon oxide thin film, the melting-resolidification process by scanning of the same laser beam was observed and as a result, it was found that the former was incompletely molten while the latter was completely molten. The silicon oxide thin film having a thickness of 150 nm reflected about 23% of the intensity of a laser beam having a wavelength of 532 nm. From these facts, it can be considered that in this Example, energy of the laser beam deposited into the amorphous silicon thin film of the region provided with the 1 μm square silicon oxide island was less than that deposited into the surrounding non-specific region by the amount described above. As a result, the energy deposited into the region of the amorphous silicon thin film provided with the 1 μm square silicon oxide island was less than the critical deposited energy thereof, so that crystal grains or crystalline clusters crystallized in the solid phase remained unmelted there, and chevron-shaped crystal grains that were 10 μm-wide and 50 μm-long on average laterally grew with scanning of the laser beam while using the unmelted crystal grains or crystalline clusters as seed crystals. Thus, it can be said that the region of the amorphous silicon thin film provided with the 1 μm square silicon oxide island, situated in the 10 μm×50 μm rectangular lattice point of the starting thin film, and the surrounding non-specific region constitute the specific region 1 and the surrounding non-specific region 2, respectively, in FIGS. 1A to 1I.

That is, this Example is an example different from Example 1-1 in that the density of energy deposited into the specific region is smaller than the density of energy deposited into the surrounding non-specific region, so that the absorption energy density in the specific region is smaller than the absorption energy density in the surrounding non-specific region and as a result, the maximum value of the accumulated energy density for melting in the specific region is smaller than the critical energy density for complete melting of the specific region, and the maximum value of the accumulated energy density for melting in the surrounding non-specific region is greater than the critical energy density for complete melting of the surrounding non-specific region.

### EXAMPLE 1-9

As ninth Example, a first example of a crystalline silicon thin film formed according to the steps shown in FIGS. 2A to 2I will be described.

The same stating thin film as that of Example 1-3 was used and laser beam irradiation was performed in the same manner as in Example 1-3 except that only the scanning rate of the laser beam was reduced to 70 mms⁻¹, whereby the same crystalline thin film as that of Example 1-3 was obtained.

For a thin film having silicon ions injected therein and a thin film having no silicon ions introduced therein, the melting-resolidification process by scanning of the laser beam of this Example was observed over a certain time period and as a result, it was found that both the thin films were completely molten unlike the case of Example 1-3. However, the latter early started resolidification after melting. For the cause of this, it can be considered that injection of silicon ions with 40 keV acceleration energy reaching near the interface between the starting thin film and the substrate changed the state of interface with the substrate contacting the starting thin film, so that the free energy barrier to crystal nucleation from the molten phase in resolidification of the former increased. Thus, in this Example, the 1 μm square region masked with the amorphous silicon oxide island and the other region constitute the specific region 1 and the surrounding non-specific region 2, respectively, in FIGS. 2A to 2I.

That is, this Example is an example in which the state of the interface with the substrate contacting the starting thin film varies between the inside and outside of the specific region, so that the free energy barrier to crystal nucleation from the molten phase in resolidification of the specific region is lower than the free energy barrier to crystal nucleation from the molten phase in resolidification of the surrounding non-specific region and as a result, crystal grains or crystalline clusters are nucleated preferentially in the specific region in the resolidification step after melting, and crystal grains laterally grow by using the nucleated crystal grains or crystalline clusters as seed crystals, and consequently a desired number of crystals or crystalline clusters grow from the specific region in spite of the fact that the specific region and the surrounding non-specific region are both completely molten.

### EXAMPLE 1-10

As tenth Example, a second example of a crystalline silicon thin film formed according to the step shown in FIGS. 2A to 2I will be described.

The same stating thin film as that of Example 1-4 was used and laser beam irradiation was performed in the same manner as in Example 1-4 except that only the scanning rate of the laser beam was reduced to 150 mms⁻¹, whereby the same crystalline thin film as that of Example 1-4 was obtained.

For a thin film having tin injected therein and a thin film having no tin introduced therein, the melting-resolidification process by scanning of the laser beam of this Example was observed over a certain time period and as a result, it was found that both the thin films were completely molten unlike the case of Example 1-4. However, the former early started resolidification after melting. For the cause of this, it can be considered that injection of tin as an impurity reduced the free energy barrier to crystal nucleation from the molten phase in resolidification of the former. Thus, in this Example, the 1 μm square region having tin injected therein and the other region constitute the specific region 1 and the surrounding non-specific region 2, respectively, in FIGS. 2A to 2I.

That is, this Example is an example different from Example 1-9 in that the concentration of impurity contained in the specific region (tin: finite) is different from the concentration of impurity contained in the surrounding non-specific region (tin: below detection limit), so that the free energy barrier to crystal nucleation from the molten phase in resolidification of the specific region is lower than the free energy barrier to crystal nucleation from the molten phase in resolidification of the surrounding non-specific region.

### EXAMPLE 1-11

As eleventh Example, a third example of a crystalline silicon thin film formed according to the steps shown in FIGS. 2A to 2I will be described.

The same stating thin film as that of Example 1-5 was used and laser beam irradiation was performed in the same manner as in Example 1-5 except that only the scanning rate of the laser beam was reduced to 150 mms⁻¹, whereby the same crystalline thin film as that of Example 1-5 was obtained.

For a thin film having nickel deposited thereon and a thin film having no nickel deposited thereon, the melting-resolidification process by scanning of the laser beam of this Example was observed over a certain time period and as a result, it was found that both the thin films were completely molten unlike the case of Example 1-5. However, the former early started resolidification after melting. For the cause of this, it can be considered that surface-adsorption of nickel reduced the free energy barrier to crystal nucleation from the molten phase in resolidification of the former. Thus, in this Example, the 1 μm square region having nickel deposited thereon and the other region constitute the specific region 1 and the surrounding non-specific region 2, respectively, in FIGS. 2A to 2I.

That is, this Example is an example different from Example 1-9 in that the surface adsorbate in the specific region (having nickel) is different from the surface adsorbate in the surrounding non-specific region (having no nickel), so that the free energy barrier to crystal nucleation from the molten phase in resolidification of the specific region is lower than the free energy barrier to crystal nucleation from the molten phase in resolidification of the surrounding non-specific region.

### EXAMPLE 1-12

As twelfth Example, a fourth example of a crystalline silicon thin film formed according to the steps shown in FIGS. 2A to 2I will be described.

The same stating thin film as that of Example 1-7 was used and laser beam irradiation was performed in the same manner as in Example 1-7 except that only the scanning rate of the laser beam was reduced to 60 mms⁻¹, whereby the same crystalline thin film as that of Example 1-7 was obtained.

A test substrate provided on a monocrystal silicon substrate with only a silicon nitride thin film having a thickness 10 nm, and a test substrate provided further on the silicon nitride thin film with a silicon oxide film having a thickness of 1 μm were prepared, a precursor of this Example was deposited on each of the test substrates, the melting-resolidification process by scanning of the same laser beam observed over a certain time period and as a result, it was shown that both the test substrates were completely molten unlike Example 1-7, the temperature of the former was lower than the temperature of the latter by 100° C. or more before and after maximum melting of the thin film, and the former very early started resolidification after melting. From these facts, it can be considered that the amorphous silicon thin film was thermally insulated by the monocrystal silicon substrate and the silicon oxide film having a sufficiently large thickness in regions around the bowl-shaped dimple, while the amorphous silicon thin film was thermally isolated by the monocrystal silicon substrate having a large heat conductivity and the silicon nitride thin film having a thickness of only 10 nm in the bottom of the bowl-shaped dimple and from this area, the heat of the heated amorphous silicon thin film flowed to the monocrystal silicon substrate at a high rate, so that after the bowl-shaped dimple region reached a maximally molten state, a period was created-over which the temperature of the bowl-shaped dimple region was lower than the temperature of the surrounding non-specific region contacting the bowl-shaped dimple region and as a result, nucleation from the molten phase occurred preferentially in the bowl-shaped dimple region, and crystal grains laterally grew with scanning of the laser beam by using the crystal nucleus as seed crystals to form chevron-shaped crystal grains that were 10 μm-wide and 50 μm-long on average. Thus, the bowl-shaped dimple region situated in the 10 μm×50 μm rectangular lattice point of the starting thin film and the surrounding non-specific region constitute the specific region 1 and the surrounding non-specific region 2, respectively, in FIGS. 2A to 2I.

That is, this Example is an example different from Example 1-9 in that the rate of thermal draining from the specific region is greater than the rate of thermal draining from the surrounding non-specific region, so that after the specific region reaches a maximally molten state, a period over which the temperature of the specific region is lower than the temperature of the surrounding non-specific region contacting the specific region is not created and as a result, crystal grains or crystalline clusters nucleated preferentially in the specific region in the resolidification step after melting, and crystal grains laterally grow using the nucleated crystal grains or crystalline clusters as seed crystals.

### EXAMPLE 1-13

As thirteenth Example, a fifth example of a crystalline silicon thin film formed according to the steps shown in FIGS. 2A to 2I will be described.

The same stating thin film as that of Example 1-8 was used and laser beam irradiation was performed in the same manner as in Example 1-8 except that only the scanning rate of the laser beam was reduced to 80 mms^{31 1}, whereby the same crystalline thin film as that of Example 1-8 was obtained.

For a thin film provided on the entire surface with a silicon oxide thin film having a thickness of 150 nm and a thin film provided with no such a silicon oxide thin film, the melting-resolidification process by scanning of the same laser beam was observed over a certain time period and as a result, it was shown that both the thin films were completely molten unlike Example 1-8, the temperature of the former was lower than the temperature of the latter by 100° C. or more before and after maximum melting of the thin film, and the former very easily started resolidification after melting. From these facts, it can be considered that energy deposited into the region of the amorphous silicon thin film provided with the 1 μm square silicon oxide island and the surrounding non-specific region was greater than critical deposited energy of these regions, but deposited energy into the former was less than deposited energy into the latter, so that after the former reached a maximally molten state, a period was created over which the temperature of the former was lower than the temperature of the surrounding non-specific region contacting the former and as a result, preferential nucleation from the molten phase occurred there, and crystal grains laterally grew with scanning of the laser beam by using the formed nucleus as seed crystals to form chevron-shaped crystal grains that were 10 μm-wide and 50 μm-long on average on average. Thus, it can be said that the region of the amorphous silicon thin film provided with the 1 μm square silicon oxide island, situated in the 10 μm×50 μm rectangular lattice point of the starting thin film, and the surrounding non-specific region constitute the specific region 1 and the surrounding non-specific region 2, respectively, in FIGS. 2A to 2I.

That is, this Example is an example different from example 1-9 in that the density of energy deposited into the specific region is smaller than the density of energy deposited into the surrounding non-specific region, so that the absorption energy density in the specific region is smaller than the absorption energy density in the surrounding non-specific region and thus after the specific region reaches a maximally molten state, a period over which the temperature of the specific region is lower than the temperature of the surrounding non-specific region contacting the specific region is created and as a result, crystal grains or crystalline clusters are nucleated preferentially in the specific region in resolidification after melting.

### EXAMPLE 1-14 As fourteenth Example, an example of an MOS-type TFT element, a TFT integrated circuit and an EL image displaying apparatus having a structure shown in FIG. 3 will be described.

First, a matrix of silicon crystal grains that were 10 μm-wide and 50 μm-long on average was provided on a glass substrate having a silicon nitride film and a silicon oxide film deposited on the surface according to the step described in Example 1-2. Then, according to a usual step of low-temperature formation of a silicon thin film transistor, a gate insulating film composed of a silicon oxide film and a gate electrode film were deposited, and the gate electrode film layer was removed except for a 1 μm-wide region in the center of the single crystal grain. Then, other regions than the gate electrode film were doped with boron to form a gate region, a source region and a drain region by a self align method using the remaining gate electrode film as a mask. Consequently, the entire area of the gate region was included in the single crystal grain. Thereafter, a passivation layer composed of an insulating film was deposited, and an opening was provided in the passivation layer on each region. Finally, an aluminum layer for wiring was deposited, and this layer was patterned to form a gate electrode, a source electrode and a drain electrode to obtain an MOS-type TFT.

Measurement of the operation characteristics of the obtained MOS-type TFT showed that it realized two times or more operation speed in the average value of mobility compared to the element formed in a randomly formed polycrystal thin film provided without the specific region of the present invention by the same step and in the same shape. In addition, in comparison of fluctuation in element characteristics, fluctuation of its mobility was reduced to about a half and fluctuation of its threshold voltage was reduced to about ¼.

Each electrode was connected to two adjacent elements of the MOS-type TFTs in the following manner. Specifically, the drain electrode of a first TFT was connected to the gate electrode of a second TFT. In addition, the gate electrode of the second TFT was connected to the source electrode of the same TFT through a capacitor element. Consequently, an integrated circuit comprised of two elements of the TFT and the capacitor element was formed. In this circuit, an electric power current supplied to the source of the second TFT undergoes control of its amount outputted from the drain of the TFT by an accumulated capacity of the capacitor element, while the accumulated capacity of the capacitor element and switching of accumulation are controlled by a gate voltage of the first TFT. This circuit can be used in, for example, an element circuit performing switching of pixels and control of the current amount in an active matrix-type displaying apparatus, and the like.

The basic operation characteristics of the circuit formed in this Example were measured, and were compared with the characteristics of the circuit formed in the randomly formed polycrystal thin film provided without the specific region 4 of the present invention by the same step and in the same shape. As a result, it was shown that it realized three times or more operation speed for an operable switching frequency, and that the controllable range of the amount of a current outputted from the drain electrode of the second TFT was expanded by about two times. In addition, in comparison of fluctuation in characteristics of a plurality of the same circuits formed, the fluctuation was reduced to about a half or less in each case. This means that not only fluctuation among first TFTs and fluctuation among second TFTs in circuits are reduced, but also the relative characteristics of the first TFT and the second TFT in one circuit are more uniform than comparative examples.

Then, wires connected to element circuits were provided in the following manner so that the TFT integrated circuits situated at square lattice points provided at intervals of 100 μm on the glass substrate were element circuits, and unit cells of those square lattices were pixels of the image displaying apparatus. First, a scan line extending through the square lattice along one axis was provided for each lattice, and the gate electrode of the first TFT in each element circuit was connected thereto. On the other hand, a signal line and an electric power line were connected in the direction orthogonal to the scan line for each lattice, and they were connected to the source electrode of the first TFT and the source electrode of the second TFT in each element circuit. Then, an insulating layer was deposited on the integrated circuit of the element circuits, and an opening for exposing the drain electrode of the second TFT was provided in each element circuit. Then, a metal electrode was deposited, and this metal electrode was insulated for each-pixel. Finally, an electroluminescence (EL) light-emitting layer and an upper transparent electrode layer were stacked. In this way, an active matrix-type multiple tone EL image displaying apparatus performing switching of pixels and control of the injected current amount by the TFT integrated circuit was formed.

That is, in this image displaying apparatus, a charge capacity corresponding to the value of a current given to the signal line by the actuation of the first TFT depending on a voltage of the scan line is accumulated from the electric power line to the capacitor element, and a current controlled by a gate voltage of the second TFT corresponding to the accumulated capacity is injected from the electric power line into the EL light-emitting layer.

The basic operation characteristics of the image displaying apparatus formed in this Example were measured, and compared with the characteristics of the image displaying apparatus formed in the randomly formed polycrystal thin film provided without the specific region 1 of the present invention by the same step and in the same shape. As a result, as static characteristics, it was shown that the maximum brightness and the maximum contrast were improved by about two times, and the tone reproduction range was expanded by about 1.5 times, and that the pixel defective percent and the unevenness of lightness were reduced to ⅓ and ½, respectively. In addition, as dynamic characteristics, the maximum frame rate was improved by about two times. The improvements in operation characteristics all come from an improvement in element circuit characteristics and a reduction in fluctuation, and they result from an improvement in characteristics of thin film transistors constituting element circuits and a reduction in fluctuation, and hence the effect of formation of the active regions of the thin film transistors in each single crystal grain.

The following Examples 2-1 to 2-3 are examples of a second method for producing a crystalline thin film according to the present invention.

### EXAMPLE 2-1

As first Example of the second method for producing a crystalline thin film according to the present invention, an example of a crystalline thin film formed according to the steps shown in FIGS. 4A to 4I, 5A to 5I and 6A to 6F will be described.

First, as a precursor, a hydrogenated amorphous silicon thin film with the thickness of 100 nm including no crystalline silicon clusters was deposited on a glass substrate, as a substrate, having an amorphous silicon oxide surface by plasma chemical vapor deposition, and subjected to dehydrogenation processing by a thermal treatment. An amorphous silicon oxide film with the thickness of 150 nm was deposited on the amorphous silicon thin film surface by a sputtering process, and patterned so that a 1 μm square amorphous silicon oxide islands were left on a 10 μm×50 μm rectangular lattice points by a photolithography step. Silicon ions were injected from the surface using the amorphous silicon oxide islands as a mask under the conditions of acceleration energy of 40 keV and dose of 2×10¹⁵ cm⁻², and then the amorphous silicon oxide islands as the mask were removed. Then, this thin film was isothermally annealed in the atmosphere of nitrogen at 600° C. for 15 hours and as a result, a single crystal grain having a grain diameter of about 3 μm grew on the 10 μm×50 μm rectangular lattice point provided with the 1 μm square amorphous silicon oxide island, and its surrounding non-specific region was still amorphous.

Then, XeCl excimer laser beam outputting pulse light was formed into a line beam having a width of 4 μm, and applied to the thin film in the energy density of 400 mJ·cm⁻². In application of the laser beam, the longitudinal direction of the spot was made to match the direction of the short axis of the rectangular lattice along which the 1 μm square regions provided with the photoresist mask of the thin film were aligned at intervals of 10 μm, and the center of the width of 4 μm of laser beam was positioned at a distance of 3 μm apart from the center of the crystal grain. Then, the same laser beam was shifted parallel in its width direction by a step of 2 μm and applied.

Observation of the obtained crystalline thin film showed that the entire region of the thin film was filled up with crystal grains that were 10 μm-wide and 50 μm-long on average, and they were arranged in the form of a rectangular lattice. Detailed observation of those crystal grains showed that they had a chevron shape, at both ends in the 50 μm length direction, having a raised portion and a recessed portion, respectively, rather than a rectangular shape. Furthermore, an apparently trace of the 1 μm square amorphous silicon oxide island used for injection of mask ions was observed in the raised portion of the chevron shape. It can be considered that the chevron-shaped crystal grain constituting the crystalline thin film of this Example was formed by using as a seed crystal a single crystal grain having the grain diameter of about 3 μm situated in the 10 μm×50 μm rectangular lattice point of the starting thin film, and by laterally growing therefrom with repetition of application and shift of the laser beam. Thus, it can be said that the region immediately under the 1 μm square amorphous silicon oxide island situated in the 10 μm×50 μm rectangular lattice point of the stating thin film, the single crystal grain with the grain diameter of about 3 μm position-controlled there, and the surrounding amorphous region constitute the specific region 2, the crystal grain 3 and the surrounding non-specific region 4, respectively, in FIGS. 4A to 4I.

That is, this Example is an example in which in the thin film on the amorphous substrate having a single crystal grain provided in a specific region by selective and preferential solid phase crystallization, a part of the boundary between the crystal grain and the surrounding non-specific region and a part of the surrounding non-specific region including an unmelted region are defined as a melting-resolidified area, and a step of making the crystal grain laterally grow by a melting-resolidification step of locally pulse-heating and completely melting and resolidifying the melting-resolidified area is repeated stepwise while shifting the melting-resolidified area so that adjacent melting-resolidified areas overlap each other, whereby the position-controlled crystal grain is made to laterally grow continuously to form a crystalline thin film with the controlled spatial position of the crystal grain.

### EXAMPLE 2-2

As second Example, an example of a crystalline silicon thin film formed according to the steps shown in FIGS. 5A to 5I and 6A to 6F will be described.

First, a thin film was prepared according to the same steps as in Example 2-1 for injection of silicon ions and removal of the amorphous silicon oxide islands. Unlike Example 2-1, solid phase crystallization by isothermal annealing in the atmosphere of nitrogen at 600° C. for 15 hours was not performed, but KrF excimer laser light was applied to the entire surface of the thin film in the energy density of 400 mJ·cm⁻²instead of forming the laser light into a line beam. Consequently, the thin film was a crystalline thin film in which crystal grains with the grain diameter of about 2 μm were aligned on a 10 μm×50 μm rectangular lattice points which had been provided with the mask of the 1 μm square amorphous silicon oxide islands, and the surrounding non-specific region thereof was filled with randomly formed fine crystal grains with the average grain diameter of about 50 nm.

Then, the same excimer laser beam as that of Example 2-1 was repeatedly applied to the crystalline thin film in the energy density of 450 mJ·cm⁻². In application of the laser beam, as in the case of Example 2-1, the longitudinal direction of the spot was made to match the direction of the short axis of the rectangular lattice along which the 1 μm square regions provided with the photoresist mask of the starting thin film were aligned at intervals of 10 μm, and they were positioned at a distance of 2 μm apart from the center of the width of 4 μm of the laser beam in first application. In second and subsequent applications, the laser beam was repeatedly applied while making a parallel shift by steps of 2 μm in the width direction of the laser beam.

Observation of the obtained crystalline thin film showed that the entire region of the thin film was filled up with crystal grains that were 10 μm-wide and 50 μm-long on average, and they were arranged in the form of a rectangular lattice as in the case of Example 2-1. It can be considered that the crystal grain constituting the crystalline thin film of this Example was formed by using as a seed crystal a single crystal grain with the grain diameter of about 2 μm situated in the 10 μm×50 μm situated in rectangular lattice point, and by laterally growing therefrom with repeated application and shift of the laser beam. From the result of observation of a crystalline thin film taken out during repeated application of the laser beam, it was found that the distance of one time lateral growth was 3 μm. This means that the 1 μm-wide region of the 4 μm-wide melting-resolidified area includes a part of the crystal grain that has previously laterally grown, in every application of the laser beam. Thus, it can be said that the region immediately under the 1 μm square amorphous silicon oxide island situated in the 10 μm×50 μ rectangular lattice point of the starting thin film, the single crystal grain with the grain diameter of about 2 μm position-controlled there, and the surrounding fine crystal region constitute the specific region 2, the crystal grain 3 and the surrounding non-specific region 9, respectively, in FIGS. 5A to 5I.

That is, this Example is an example different from Example 2-1 in that in the thin film on the amorphous substrate having a single crystal grain provided in a specific region by selective and preferential melting-resolidification, not only a part of the boundary between the position-controlled crystal grain and the surrounding non-specific region but also a part of the crystal grain are used as a melting-resolidified area.

### EXAMPLE 2-3

As third Example, an example of a crystalline silicon thin film formed according to the steps shown in FIGS. 5A to 5I and 6A to 6F, which is different from Example 2-2, will be described.

First, a thin film was prepared according to the same steps as in Example 2-2 for injection of silicon ions and removal of the amorphous silicon oxide islands. Unlike Example 2-2, laser light not formed into a line beam was not applied, but processing directly proceeded to the step of repeatedly applying the line beam described below.

That is, the same KrF excimer laser light formed into a line beam spot, as that of Example 2-2, was repeatedly applied to the amorphous silicon thin film. In application of the laser beam, the longitudinal direction of the spot was made to match the direction of the short axis of the rectangular lattice along which the 1 μm square regions provided with the photoresist mask of the starting thin film were aligned at intervals of 10 μm, as in the case of Example 2-2. In first application, they were positioned at the center of the width of 4 μm of the laser beam, and the laser beam was applied in the energy density of 400 mJ·cm⁻². In second and subsequent applications, the energy density was increased to 500 mJ·cm⁻², and the laser beam was repeatedly applied while making a parallel shift by steps of 2 μm in the width direction of the laser beam.

Observation of the obtained crystalline thin film showed that the entire region of the thin film was filled up with crystal grains that were 10 μm-wide and 50 μm-long on average, and they were arranged in the form of a rectangular lattice as in the case of Example 2-2. In this connection, observation of the thin film immediately after first application of the laser beam showed that crystal grains with the grain diameter of about 2 μm were aligned on the 10 μm×50 μm rectangular lattice points that had been provided with the mask of the 1 μm square amorphous silicon oxide islands, the surrounding non-specific region with the width of about 4 μm irradiated with the laser beam was filled with randomly formed fine crystal grains with the average grain diameter of about 50 nm, and the outer side thereof was still amorphous. It can be considered that the crystal grain constituting the crystalline thin film of this Example was formed by using as a seed crystal a single crystal grain with the grain diameter of about 2 μm situated in the 10 μm×50 μm rectangular lattice point in the first application of the laser beam, and by laterally growing therefrom with repetition of second and subsequent applications and shifts of the laser beam. Thus, it can be said that the region immediately under the 1 μm square amorphous silicon oxide island situated in the 10 μm×50 μm rectangular lattice point of the starting thin film, the single crystal grain with the grain diameter of about 2 μm position-controlled there in the first application of the laser beam, and the surrounding fine crystal region and amorphous region constitute the specific region 2, the crystal grain 3 and the surrounding non-specific regions 4 and 9, respectively, in FIGS. 5A to 5I.

That is, this Example is an example different from Example 2-2 in that the step of making the single crystal grain grow in the specific region by melting-resolidification, and the step of making the crystal grain laterally grow by stepwise shift of the melting-resolidified area are continuously carried out using the same heating means.

1. A process for producing a crystalline thin film by melting and resolidifying a thin film, comprising the steps of:
(A) preparing a thin film having a specific region arranged at a predetermined position, the specific region being continuous to a surrounding non-specific region and different in melting or resolidification property from the surrounding non-specific region;
(B) locally melting and resolidifying a partial area including the specific region in the thin film; and
(C) locally melting and resolidifying another partial area including a non-specific region sharing a common boundary with an area crystallized by resolidification in a preceding step.

2. The process for producing-a crystalline thin film according to claim 1, wherein the step (C) is repeated while shifting the area to be locally molten in one direction, whereby the crystallized area is made to grow in the direction of shifting.

3. The process for producing a crystalline thin film according to claim 2, wherein the step (A) is a step of preparing a thin film in which a plurality of specific regions are aligned in line, the step (B) is a step of melting and resolidifying an area including two or more specific regions among the plurality of specific regions, and the step (C) is repeated while shifting the area to be locally molten in a direction almost orthogonal to a direction along which the plurality of specific regions are aligned.

4. The process for producing a crystalline thin film according to claim 2, wherein the step (A) is a step of preparing a thin film in which a plurality of specific regions are aligned in line, and the step of (C) is repeated while shifting the area to be locally molten in a direction along which the plurality of specific regions are aligned.

5. The process for producing a crystalline thin film according to claim 1, wherein the step of (B) is a step of locally melting the non-specific region, and continuously shifting the molten area to make the molten area pass through the specific region, thereby melting and resolidifying the specific region.

6. The process for producing a crystalline thin film according to claim 1, wherein the step (C) is carried out while continuously shifting the molten area subsequently to the preceding step.

7. The process for producing a crystalline thin film according to claim 2, wherein the step (C) is repeated while continuously shifting the area to be locally molten in one direction, whereby the crystallized area is made to grow in the direction of shifting.

8. The process for producing a crystalline thin film according to claim 1, wherein the step (C) is a step in which the partial area is locally heated pulsewise, and molten and resolidified.

9. The process for producing a crystalline thin film according to claim 8, wherein the step (C) is repeated while shifting stepwise the area to be locally molten in one direction, whereby the crystallized area is made to grow in the direction of shifting.

10. The process for producing a crystalline thin film according to claim 8, wherein in the step (C), the area to be molten includes a part of the area crystallized in the preceding step.

11. The process for producing a crystalline thin film according to claim 8, wherein in the step (C) that is repeatedly carried out, the area to be molten includes an area that is not yet molten and resolidified.

12. The process for producing a crystalline thin film according to claim 1, wherein a spatial position of the specific region in the thin film is controlled, whereby a spatial position of at least a part of the crystal grain having a continuous crystal structure in the crystalline thin film is controlled.

13. A process for producing a crystalline thin film, comprising providing a specific region in a thin film, locally melting a partial area of the thin film, and shifting the locally molten partial area to be made to pass through the specific region.

14. The process for producing a crystalline thin film according to claim 13, wherein an area that is altered by melting of the thin film contacts only a surface having no crystal structure continuous to the crystalline thin film after alteration.

15. The process for producing a crystalline thin film according to claim 13, wherein a desired number of crystal grains or crystalline clusters grow from the specific region.

16. The process for producing a crystalline thin film according to claim 15, wherein the crystal grains or crystalline clusters are crystal grains or crystalline clusters remaining unmelted in the specific region when the thin film is molten.

17. The process for producing a crystalline thin film according to claim 16, wherein a maximum value of an accumulated energy density for melting in the specific region is smaller than a critical energy density for complete melting of the specific region, and a maximum value of an accumulated energy density for melting in its surrounding region is greater than a critical energy density for complete melting of the surrounding region.

18. The process for producing a crystalline thin film according to claim 17, wherein the critical energy density for complete melting of the specific region is greater than the critical energy density for complete melting of the surrounding region.

19. The process for producing a crystalline thin film according to claim 18, wherein a thickness of the specific region is greater than a thickness of the surrounding region.

20. The process for producing a crystalline thin film according to claim 18, wherein a rate of thermal draining from the specific region is greater than a rate of thermal draining from the surrounding region.

21. The process for producing a crystalline thin film according to claim 17, wherein an absorption energy density of the specific region is smaller than an absorption energy density of the surrounding region.

22. The process for producing a crystalline thin film according to claim 21, wherein a density of energy deposited into the specific region is smaller than a density of energy deposited into the surrounding region.

23. The process for producing a crystalline thin film according to claim 15, wherein the crystal grains or crystalline clusters are crystal grains or crystalline clusters nucleated from a molten phase in resolidification after melting of the specific region.

24. The process for producing a crystalline thin film according to claim 23, wherein the specific region and the surrounding region are both completely molten.

25. The process for producing a crystalline thin film according to claim 23, wherein a free energy barrier to crystal nucleation from the molten phase in resolidification of the specific region is lower than a free energy barrier to crystal nucleation from the molten phase in resolidification of the surrounding region.

26. The process for producing a crystalline thin film according to claim 25, wherein at least any one of a composition ratio of elements of the thin film, an impurity concentration, a surface adsorbate, and a state of an interface between a substrate and the thin film is different between the inside and outside of the specific region.

27. The process for producing a crystalline thin film according to claim 23, wherein a period over which a temperature of the specific region is lower than a temperature of a vicinal region of surrounding and contacting the specific region is created after the specific region of a starting thin film reaches a maximally molten state.

28. The process for producing a crystalline thin film according to claim 27, wherein the rate of thermal draining from the specific region is greater than the rate of thermal draining from the surrounding region.

29. The process for producing a crystalline thin film according to claim 27, wherein an absorption energy density of the specific region is smaller than an absorption energy density of the surrounding region.

30. The process for producing a crystalline thin film according to claim 29, wherein a density of energy deposited into the specific region is smaller than a density of energy deposited into the surrounding region.

31. A process for producing a crystalline thin film, wherein an area including a part of a boundary between a position-controlled crystal grain of a thin film and the surrounding region is made a melting-resolidified area, and the crystal grain is made to laterally grow by a melting-resolidification step in which the melting-resolidified area is locally heated pulsewise, and molten and resolidified.

32. The process for producing a crystalline thin film according to claim 31, wherein a surface of the thin film of the melting-resolidified area contacts only a surface of a substrate having no crystal structure continuous to the crystalline thin film.

33. The process for producing a crystalline thin film according to claim 31, wherein the melting-resolidified area includes a part of the crystal grain.

34. The process for producing a crystalline thin film according to claim 31, wherein the surrounding region of the position-controlled crystal grain is completely molten in the melting-resolidification step.

35. The process for producing a crystalline thin film according to claim 31, wherein after the melting-resolidification step, the melting-resolidified area is shifted in a direction along which the crystal grain grows, and the melting-resolidification step is carried out again, whereby the crystal grains are made to further laterally grow.

36. The process for producing a crystalline thin film according to claim 35, wherein the melting-resolidification step to be carried out again is repeatedly carried out multiple times.

37. The process for producing a crystalline thin film according to claim 35, wherein the melting-resolidified area in the melting-resolidification step to be carried out again and the melting-resolidified area in the immediately preceding melting-resolidification step partially overlap each other.

38. The process for producing a crystalline thin film according to claim 35, wherein the melting-resolidified area in the melting-resolidification step to be carried out again includes a grain boundary of a crystal grain having a crystal structure continuous to a position-controlled crystal grain.

39. The process for producing a crystalline thin film according to claim 35, wherein the melting-resolidified area in the melting-resolidification step to be carried out again includes an area that is not yet made the melting-resolidificated area.

40. The process for producing a crystalline thin film according to claim 31, the position-controlled crystal grain is a single crystal grain provided in the specific region of a precursor of the thin film.

41. The process for producing a crystalline thin film according to claim 40, wherein the precursor of the thin film is an amorphous thin film, and the single crystal grain provided in the specific region is a crystal grain grown by solid phase crystallization of the amorphous thin film.

42. The process for producing a crystalline thin film according to claim 40, wherein the single crystal grain provided in the specific region is a crystal grain grown in the specific region by melting-resolidification of the precursor of the thin film.

43. The process for producing a crystalline thin film according to claim 42, wherein a step of providing the single crystal grain in the specific region and the step of making the single crystal grain laterally grow according to claim 31 are continuously carried out using the same heating means.

44. An element formed by using the crystalline thin film obtained in the process of claim 1, wherein a spatial position of at least a part of a crystal grain having a continuous crystal structure is determined by a spatial position of a specific region in a starting thin film, and a crystal grain having the controlled spatial position is used in an active region.

45. The element according to claim 44, wherein the active region is formed in a single crystal grain of the crystalline thin film.

46. A circuit comprising a plurality of elements of claim 45, wherein the elements are connected to one another by a wire.
